(19) United States
(12) Patent Application Publication
(10) Pub. No.: US 2025/0107430 A1
(43) Pub. Date: Mar. 27, 2025

(54) LIGHT EMITTING COMPOSITION, ORGANIC LIGHT EMITTING DEVICE, DISPLAY APPARATUS, IMAGING APPARATUS, ELECTRONIC EQUIPMENT, LIGHTING APPARATUS, MOVING BODY, AND METHOD FOR MANUFACTURING ORGANIC LIGHT EMITTING DEVICE

(71) Applicant: CANON KABUSHIKI KAISHA, Tokyo (JP)

(72) Inventor: YUTAKA TANI, Kanagawa (JP)

(21) Appl. No.: 18/970,726

(22) Filed: Dec. 5, 2024

Related U.S. Application Data
(63) Continuation of application No. PCT/JP2023/020575, filed on Jun. 2, 2023.

(30) Foreign Application Priority Data
Jun. 7, 2022 (JP) 2022-092220
May 11, 2023 (JP) 2023-078904

(51) Int. Cl. H10K 85/30; C09K 11/02; C09K 11/06; H10K 50/12; H10K 71/13; H10K 85/10; H10K 85/60

(52) U.S. Cl. CPC H10K 85/342; C09K 11/02; C09K 11/06; H10K 71/13; H10K 85/113; H10K 85/115; H10K 85/151; H10K 85/626; H10K 85/654; C09K 2211/1007; C09K 2211/1011; C09K 2211/1014; C09K 2211/1029; C09K 2211/185; H10K 50/12

(57) ABSTRACT

A light emitting composition or the like that can improve the emission quantum yield of dopant emission and reduce the light emission of a host. The light emitting composition contains a specific organometallic complex, a specific fluorene oligomer, and a polymer host material.

### CROSS-REFERENCE TO RELATED APPLICATIONS

This application is a Continuation of International Patent Application No. PCT/JP2023/020575, filed Jun. 2, 2023, which claims the benefit of Japanese Patent Application No. 2022-092220, filed Jun. 7, 2022 and No. 2023-078904, filed May 11, 2023, both of which are hereby incorporated by reference herein in their entirety.

### TECHNICAL FIELD

The present invention relates to a light emitting composition, an organic light emitting device, a display apparatus, an imaging apparatus, electronic equipment, a lighting apparatus, a moving body, and a method for manufacturing an organic light emitting device.

### BACKGROUND ART

An organic light emitting device (organic LED) is an electronic element including a pair of electrodes of a first electrode and a second electrode and organic compound layers disposed between the pair of electrodes. Electrons and holes are injected from the pair of electrodes into the organic compound layers to activate a light emitting organic compound in the organic compound layers from its ground state to an excited state and, when the organic compound returns from the excited state to the ground state, excess energy is emitted as light. An organic light emitting device is also referred to as an organic electroluminescent device or an organic EL device.

Light emitting organic compounds are broadly classified into fluorescent materials and phosphorescent materials based on the principle of light emission. In the electrical generation of an exciton in an organic light emitting device, based on the quantum-mechanical principle, singlet energy constitutes 25%, and triplet energy constitutes 75%. Thus, it is known that a phosphorescent material that emits light from a triplet excited state has higher light emission efficiency than a fluorescent material that emits light from a singlet excited state. For example, Ir(piq)₃ [tris [1-phenylisoquinoline-C2,N]iridium (III)], which is an organometallic complex with the following structure, is known as a red phosphorescent material.

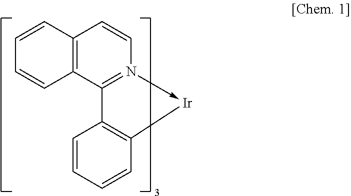

An organic light emitting device has been manufactured by a so-called vapor deposition method of heating and depositing materials for forming various functional layers, such as an organic compound layer, an inorganic compound layer, and an electrode, on a substrate under high vacuum. In the vapor deposition method, however, it is difficult to perform uniform vapor deposition on a large-area substrate, and there are problems in material utilization, manufacturing costs, and the like.

In recent years, a printing method has been studied as a method for manufacturing an organic light emitting device that can solve these problems of the vapor deposition method. In the printing method, a liquid composition containing various materials is applied to a substrate to manufacture an organic light emitting device. Since it is necessary to apply a liquid composition to a substrate to uniformly form a film, the use of polymeric or oligomeric materials with high film formability and film stability as host materials has been studied.

Non Patent Literature 1 and Non Patent Literature 2 describe the manufacturing of a device by a printing method using a composition containing a polymeric material and an Ir complex. Patent Literature 1 describes a composition containing a fluorene oligomer and an Ir complex. Patent Literature 2 describes a composition in which an oligomer and a polymeric material are used in combination as a host material.

From the perspective of high efficiency and long life of an organic light emitting device, it is important that the energy of an exciton generated by recombination of an electron and a hole is rapidly transferred to a light emitting material. A phosphorescent material as a light emitting material can efficiently utilize triplet energy. In such a case, to utilize singlet energy, it is necessary to undergo singlet energy transfer from a host to a dopant and intersystem crossing from a singlet to a triplet. When the singlet energy transfer and the intersystem crossing are not rapidly performed, the singlet energy is lost as nonradiative deactivation, light emission of the host itself, or the like. Many of polymeric or oligomeric materials used in the printing method have light emitting properties. Thus, when light emission of the host as an energy deactivation path occurs, not only the dopant emission is reduced, but also color purity is reduced due to color mixing of light emission from the host with a hue different from a desired hue.

The present inventors investigated various characteristics of the compositions described in Patent Literature 1 and Patent Literature 2. As a result, it was found that light emission of a host resulted in an insufficient emission quantum yield of a dopant.

### CITATION LIST

### Patent Literature

PTL 1 International Publication No. 2017/038613
PTL 2 Japanese Patent Laid-Open No. 2009-071222

### Non Patent Literature

NPL 1 Thin Solid Films, 2006, 499, 359-363
NPL 2 J. Mater. Chem., 2012, 22, 4660-4668

### SUMMARY OF INVENTION

Accordingly, it is an object of the present invention to provide a light emitting composition that can improve the emission quantum yield of dopant emission and reduce the light emission of a host. It is another object of the present invention to provide an organic light emitting device, a display apparatus, an imaging apparatus, electronic equipment, a lighting apparatus, and a moving body, each of which has a light emitting layer formed of the light emitting composition. It is still another object of the present invention to provide a method for manufacturing an organic light emitting device using the light emitting composition.

These objects can be achieved by the present invention as described below. A light emitting composition according to the present invention is a light emitting composition containing an organometallic complex, a fluorene oligomer, and a polymer host material, wherein the organometallic complex is at least one compound selected from the group consisting of a compound represented by the following general formula (1) and a compound represented by the following general formula (2), and the fluorene oligomer contains a unit represented by the following general formula (6), and the number of repetitions of the unit represented by the general formula (6) is 6 or more and 14 or less.

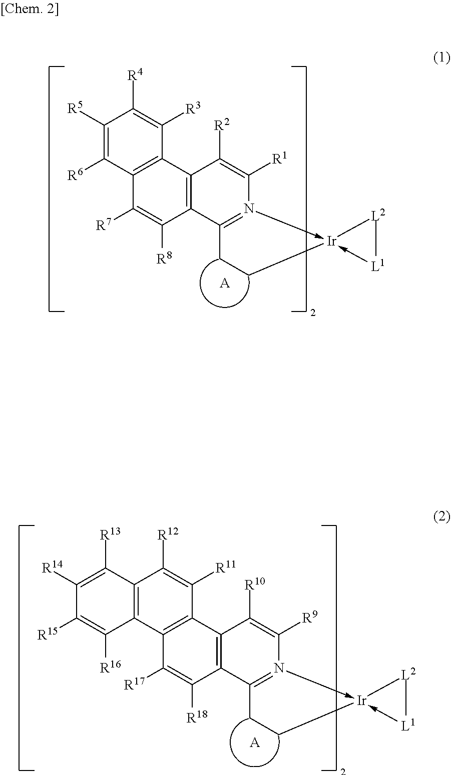

(In the general formulae (1) and (2), R¹ to R¹⁸ each independently denote a hydrogen atom, a deuterium atom, a halogen atom, an alkyl group, a cycloalkyl group, an alkoxy group, an aryl group, a heteroaryl group, an aryloxy group, a heteroaryloxy group, a silyl group, an alkoxycarbonyl group, an acyl group, or a cyano group. The ring A represents an aryl ring or a heteroaryl ring. L¹-L² represents a bidentate ligand represented by any one of the following general formulae (3) to (5).)

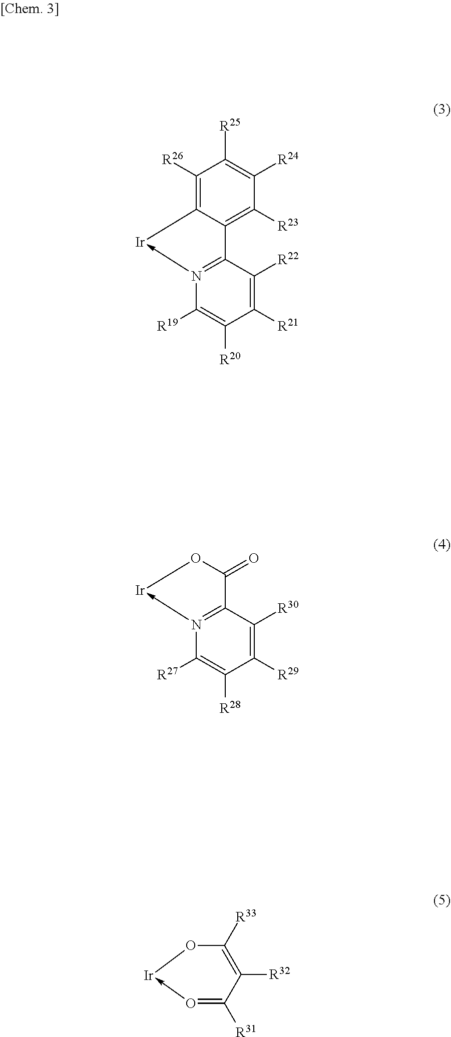

(In the general formulae (3) to (5), R¹⁹ to R³³ each independently denote a hydrogen atom, a deuterium atom, a halogen atom, an alkyl group, a cycloalkyl group, an alkoxy group, an aryl group, or a heteroaryl group.)

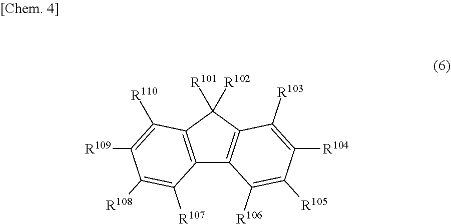

(In the general formula (6), R¹⁰¹ and R¹⁰² each independently denote a hydrogen atom, a deuterium atom, a halogen atom, an alkyl group, a cycloalkyl group, an alkoxy group, an aryloxy group, or a heteroaryloxy group, and a plurality of units represented by the general formula (6) are bonded together at any one of R¹⁰³ to R¹⁰⁶ and any one of R¹⁰⁷ to R¹¹⁰. R¹⁰³ to R¹¹⁰ that are not bonded to an adjacent molecular unit of the general formula (6) each independently denote a hydrogen atom, a deuterium atom, a halogen atom, an alkyl group, a cycloalkyl group, an alkoxy group, an aryl group, a heteroaryl group, an aryloxy group, a heteroaryloxy group, or an amino group.)

Further features of the present invention will become apparent from the following description of exemplary embodiments with reference to the attached drawings.

### BRIEF DESCRIPTION OF DRAWINGS

FIG. 1A is a schematic cross-sectional view of an example of a pixel of a display apparatus according to an embodiment of the present invention.

FIG. 1B is a schematic cross-sectional view of an example of a display apparatus including an organic light emitting device according to an embodiment of the present invention.

FIG. 2 is a schematic view of an example of a display apparatus including an organic light emitting device according to an embodiment of the present invention.

FIG. 3A is a schematic view of an example of an imaging apparatus according to an embodiment of the present invention.

FIG. 3B is a schematic view of an example of a mobile device according to an embodiment of the present invention.

FIG. 4A is a schematic view of an example of a display apparatus according to an embodiment of the present invention.

FIG. 4B is a schematic view of an example of a foldable display apparatus.

FIG. 5A is a schematic view of an example of a lighting apparatus according to an embodiment of the present invention.

FIG. 5B is a schematic view of an automobile as an example of a moving body according to an embodiment of the present invention.

FIG. 6A is a schematic view of an example of a wearable device according to an embodiment of the present invention.

FIG. 6B is a schematic view of an example of a wearable device according to an embodiment of the present invention including an imaging apparatus.

### DESCRIPTION OF EMBODIMENTS

The present invention is further described in the following preferred embodiments. The present invention is not limited to the following description, and it is easily understood by those skilled in the art that modes and details thereof can be modified in various ways without departing from the gist and scope of the present invention. Thus, the present invention is not construed as being limited by the following description. Unless otherwise specified, physical properties are values at normal temperature (25° C.). A light emitting composition according to the present invention may emit light by itself, or a member formed of the composition may emit light, and the light emitting composition is described as a “light emitting composition” in the sense of including these.

The present inventors have conducted studies on improving the emission quantum yield of dopant emission and reducing the light emission of a host by a material to be contained in a light emitting composition. As a result, the present inventors have found that the above effects can be obtained by a light emitting composition containing a specific organometallic complex, a specific fluorene oligomer, and a polymer host material. The organometallic complex is at least one compound selected from the group consisting of a compound represented by the general formula (1) and a compound represented by the general formula (2) described later. The fluorene oligomer is a compound containing a unit represented by the general formula (6) and having a number of repetitions of the unit of 6 or more and 14 or less. The present inventors speculate the mechanism for improving the emission quantum yield of dopant emission and suppressing the light emission of a host by a light emitting composition according to the present invention as described below.

A compound represented by the general formula (1) and a compound represented by the general formula (2), which are organometallic complexes, are iridium complexes having a benzoisoquinoline compound as a ligand and are red dopants. A polymer host material corresponding to the red dopant is, for example, a polycarbazole polymer or a polyfluorene polymer, which is generally used as a host material of an organic LED.

However, the polyvinylcarbazole compound and the organometallic complex (red dopant) have a large difference in S1 energy. The S1 energy refers to energy in an excited singlet state (S1). This is less likely to cause energy transfer from the host to the dopant and may decrease the emission quantum yield of dopant emission. The difference in S1 energy between the polyfluorene compound and the organometallic complex (red dopant) is smaller than that in the case of the polyvinylcarbazole compound. Thus, energy transfer from the host to the dopant is likely to occur. On the other hand, the polyfluorene compound has a rigid molecular structure and is therefore likely to aggregate. Thus, a trap site is formed, and the polyfluorene compound (host) itself emits blue light and lowers the color purity of red light emission of the red dopant.

In the present invention, a compound (fluorene oligomer) containing a unit represented by the general formula (6) is used. This can improve the emission quantum yield of dopant emission and suppress the light emission of a host. This is probably because the compound (fluorene oligomer) containing the unit represented by the general formula (6) assists energy transfer from a polymer host material with higher S1 energy to an organometallic complex (dopant).

However, the compound containing the unit represented by the general formula (6) itself is also rigid similarly to the polyfluorene compound. A fluorene oligomer used in the present invention has a number of repetitions of the unit represented by the general formula (6) in the range of 6 or more and 14 or less, has an appropriately compact molecular size, therefore suppresses the aggregation of a polymer host material, and is less likely to form a trap site. In the present description, the number of repetitions of the unit represented by the general formula (6) in a fluorene oligomer can be, in other words, the number of carbazole skeletons each having a structure in which one benzene ring is fused to each of the 2,3-position and the 4,5-position of pyrrole. When a plurality of carbazole skeletons share one benzene ring, however, the fused carbazole skeletons are collectively counted as one repeating unit. For example, a compound 116 described later has a number of repetitions of 7. When the number of repetitions is less than 6, a trap site is less likely to be formed, but energy transfer from a polymer host material to a dopant cannot be assisted. This cannot improve the emission quantum yield of dopant emission and cannot suppress the light emission of a host. On the other hand, when the number of repetitions is more than 14, the molecule has a large size and tends to be rigid similarly to a polyfluorene compound, so that the aggregation of a polymer host material cannot be suppressed, and a trap site is formed. This cannot improve the emission quantum yield of dopant emission and cannot suppress the light emission of a host.

### <Light Emitting Composition>

A light emitting composition according to the present invention contains a specific organometallic complex, a fluorene oligomer, and a polymer host material. Components constituting a light emitting composition according to the present invention and the physical properties are described in detail below.

### (Organometallic Complex)

The light emitting composition contains an organometallic complex. The organometallic complex is at least one compound selected from the group consisting of a compound represented by the general formula (1) and a compound represented by the general formula (2).

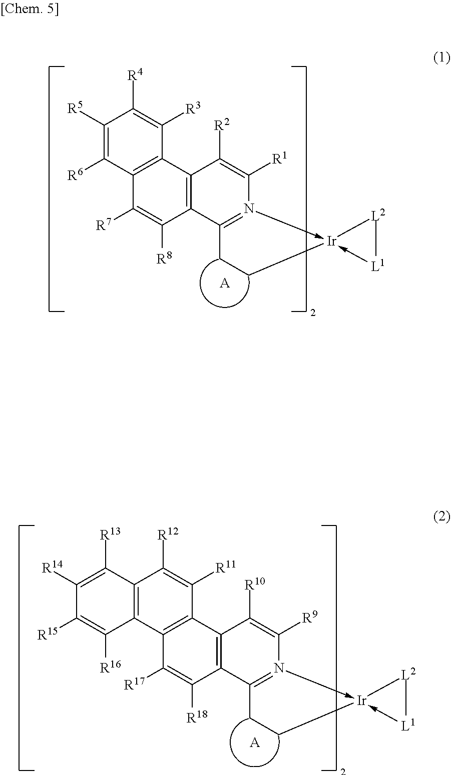

(In the general formulae (1) and (2), R¹ to R¹⁸ each independently denote a hydrogen atom, a deuterium atom, a halogen atom, an alkyl group, a cycloalkyl group, an alkoxy group, an aryl group, a heteroaryl group, an aryloxy group, a heteroaryloxy group, a silyl group, an alkoxycarbonyl group, an acyl group, or a cyano group. A ring A represents an aryl ring or a heteroaryl ring. L¹-L² represents a bidentate ligand represented by at least one of the following general formulae (3) to (5).)

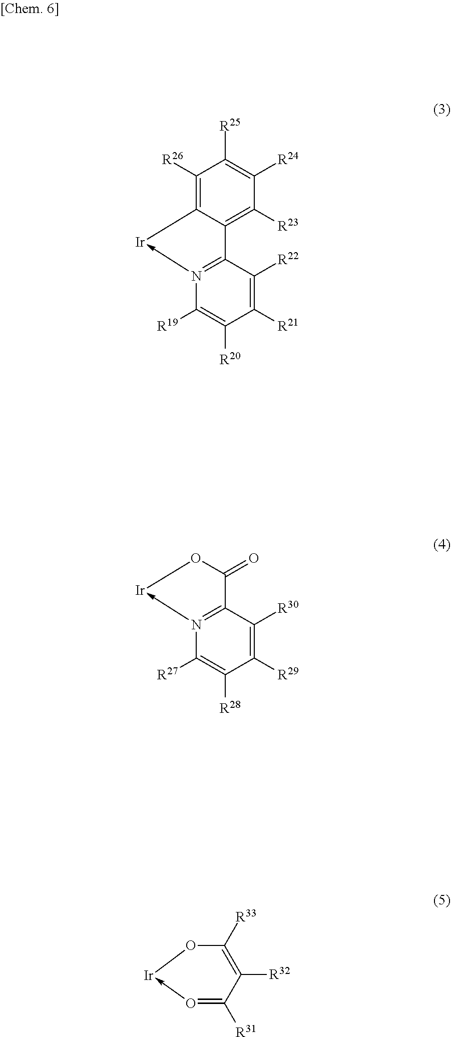

(In the general formulae (3) to (5), R¹⁹ to R³³ each independently denote a hydrogen atom, a deuterium atom, a halogen atom, an alkyl group, a cycloalkyl group, an alkoxy group, an aryl group, or a heteroaryl group.)

An arrow in the general formulae (1) to (5) means that an atom is coordinately bonded to a metal atom.

In the general formulae (1) and (2), R¹ to R¹⁸ each independently denote a hydrogen atom, a deuterium atom, a halogen atom, an alkyl group, a cycloalkyl group, an alkoxy group, an aryl group, a heteroaryl group, an aryloxy group, a heteroaryloxy group, a silyl group, an alkoxycarbonyl group, an acyl group, or a cyano group.

The halogen atom is, for example, a fluorine atom, a chlorine atom, a bromine atom, or an iodine atom. Among these, the fluorine atom is preferred from the perspective of thermal stability.

The alkyl group may be a linear or branched alkyl group with 1 to 30 carbon atoms, preferably 1 to 20 carbon atoms. More specifically, the alkyl group may be a methyl group, an ethyl group, a n-propyl group, an i-propyl group, a n-butyl group, a tert-butyl group, a sec-butyl group, an octyl group, or the like. The alkyl group may be substituted with a halogen atom (such as one exemplified above), a cyano group, or a nitro group. Furthermore, one methylene group or two or more non-adjacent methylene groups of the alkyl group may be interrupted or substituted by —O—, —S—, —C(═O)—, —C(═O)O—, —O(C═O)—, —CH═CH—, or —C≡C—.

The cycloalkyl group may be a cycloalkyl group with 3 to 30 carbon atoms, preferably 3 to 20 carbon atoms. More specifically, the cycloalkyl group may be a cyclopropyl group, a cyclohexyl group, a 1-adamantyl group, a 2-adamantyl group, or the like. The cycloalkyl group may be substituted with a halogen atom, a cyano group, or a nitro group.

The alkoxy group may be an alkoxy group with 1 to 20 carbon atoms. More specifically, the alkoxy group may be a methoxy group, an ethoxy group, a propoxy group, a 2-ethyl-octyloxy group, or the like. The alkoxy group may be substituted with a halogen atom, a cyano group, a nitro group, or an aryl group with 6 to 30 carbon atoms. The halogen atom may be the same as the halogen atom in R¹ to R¹⁸ in the general formulae (1) and (2).

The aryl group may be an aryl group with 6 to 30 carbon atoms and may be a monocyclic ring or a fused ring. More specifically, the aryl group may be a phenyl group, a naphthyl group, a biphenyl group, a fluorenyl group, a phenanthrenyl group, an anthracenyl group, a carbazolyl group, a dibenzofuryl group, a dibenzothienyl group, or the like. Furthermore, the aryl group may be substituted with a halogen atom, a cyano group, an alkyl group, or an alkoxy group. The halogen atom, the alkyl group, and the alkoxy group may be the same as those described for R¹ to R¹⁸ in the general formulae (1) and (2).

The heteroaryl group may be a heteroaryl group with 3 to 15 atoms constituting the ring and may be a monocyclic ring or a fused ring. The heteroatom may be a nitrogen atom, an oxygen atom, a sulfur atom, a silicon atom, a phosphorus atom, a germanium atom, or a combination thereof. More specifically, the heteroaryl group may be a pyridyl group, a pyrimidyl group, a pyrazyl group, a triazyl group, a benzofuranyl group, a benzothiophenyl group, a dibenzofuranyl group, a dibenzothiophenyl group, an oxazolyl group, an oxadiazolyl group, a thiazolyl group, a thiadiazolyl group, a carbazolyl group, an acridinyl group, a phenanthrolyl group, or the like. The heteroaryl group may be substituted with a halogen atom, a cyano group, an alkyl group, or an alkoxy group. The halogen atom, the alkyl group, and the alkoxy group may be the same as those described for R¹ to R¹⁸ in the general formulae (1) and (2).

The aryloxy group may be an aryloxy group having an aryl moiety with 6 to 30 carbon atoms. More specifically, the aryloxy group may be a phenoxy group, a naphthoxy group, or the like. The aryloxy group may be substituted with a halogen atom, a cyano group, an alkyl group, or an alkoxy group. The halogen atom, the alkyl group, and the alkoxy group may be the same as those described for R¹ to R¹⁸ in the general formulae (1) and (2).

The heteroaryloxy group may be a heteroaryloxy group with 3 to 15 atoms constituting the ring of the heteroaryl moiety and may be a monocyclic ring or a fused ring. The heteroatom may be the same as the heteroatom of the heteroaryl group in R¹ to R¹⁸ in the general formulae (1) and (2). More specifically, the heteroaryloxy group may be a pyridyloxy group, a pyrimidyloxy group, a pyrazyloxy group, a triazyloxy group, a benzofuryloxy group, a dibenzofuryloxy group, a benzothienyloxy group, a dibenzothienyloxy group, a pyrrolyloxy group, an indolyloxy group, an N-methylcarbazolyloxy group, or the like.

The silyl group is a group with an alkyl group, an aryl group, or an alkoxy group on a silicon atom. The silyl group may be a trialkylsilyl group, a dialkylarylsilyl group, an alkyldiarylsilyl group, a triarylsilyl group, or the like. Among these, a silyl group substituted with an alkyl group with 1 to 8 carbon atoms or substituted with an aryl group with 6 to 10 carbon atoms is preferred. Specific examples thereof include a trimethylsilyl group, a tert-butyldimethylsilyl group, a triisopropylsilyl group, a tert-butyldiphenylsilyl group, and the like.

The acyl group may be an acyl group with 1 to 20 carbon atoms. More specifically, the acyl group may be a formyl group, an acetyl group, a propionyl group, a benzoyl group, or the like.

The alkoxycarbonyl group may be an alkoxycarbonyl group with 2 to 20 carbon atoms. More specifically, the alkylcarbonyl group may be a methoxycarbonyl group, an ethoxycarbonyl group, a hexyloxycarbonyl group, or the like.

In the general formulae (1) and (2), the ring A represents an aryl ring or a heteroaryl ring. The ring A may be substituted with the group described above, that is, a halogen atom, an alkyl group, a cycloalkyl group, an alkoxy group, an aryl group, a heteroaryl group, an aryloxy group, a heteroaryloxy group, a silyl group, an alkoxycarbonyl group, an acyl group, or a cyano group. The aryl ring of the ring A may be an aryl ring with 6 to 30 carbon atoms and may be a monocyclic ring or a fused ring. Among these, the aryl ring of the ring A in the general formulae (1) and (2) is preferably a benzene ring, a naphthalene ring, a fluorene ring, a phenanthrene ring, a 9,9-spirobifluorene ring, or a chrysene ring. The heteroaryl ring of the ring A may be the same as the heteroaryl group in R¹ to R¹⁸ in the general formulae (1) and (2). Specific examples thereof include a pyridine ring, a pyrimidine ring, a pyrazine ring, a triazine ring, a benzofuran ring, a benzothiophene ring, a dibenzofuran ring, a dibenzothiophene ring, an oxazoline ring, an oxadiazole ring, a thiazole ring, a thiadiazole ring, a carbazole ring, an acridine ring, a phenanthroline ring, and the like.

In the general formulae (1) and (2), L¹-L² represents a bidentate ligand represented by at least one of the general formulae (3) to (5). In the general formulae (3) to (5), R¹⁹ to R³³ each independently denote a hydrogen atom, a deuterium atom, a halogen atom, an alkyl group, a cycloalkyl group, an alkoxy group, an aryl group, or a heteroaryl group. The halogen atom, the alkyl group, the cycloalkyl group, the alkoxy group, the aryl group, and the heteroaryl group in R¹⁹ to R³³ may be the same as those described for R¹ to R¹⁸.

Specific examples of the organometallic complex (the compound represented by the general formula (1) or the compound represented by the general formula (2)) are described below. As a matter of course, the present invention is not limited to the specific examples and includes those represented by the general formula (1) and the general formula (2).

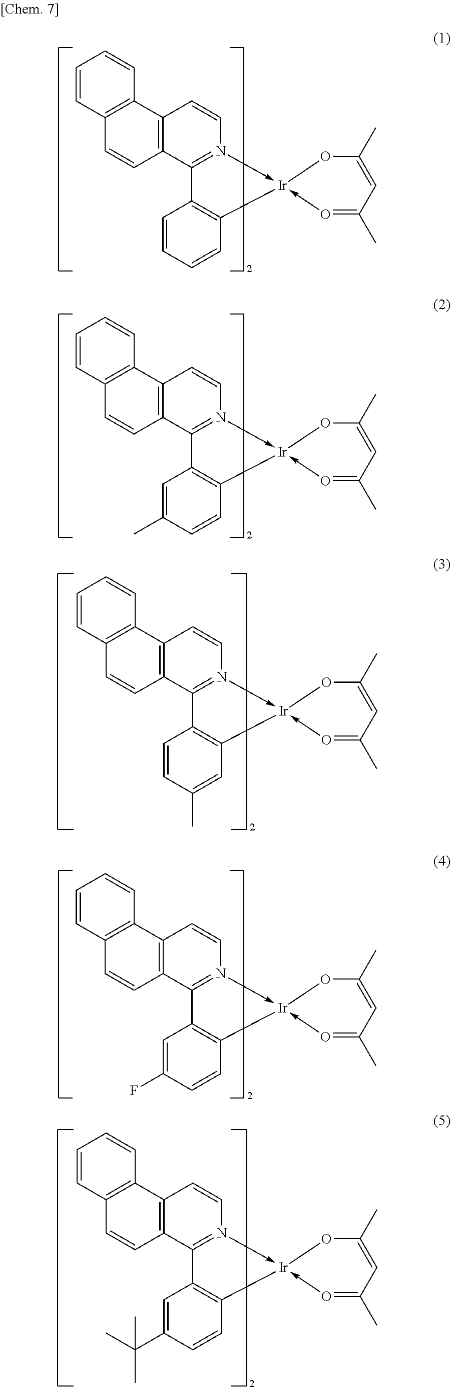

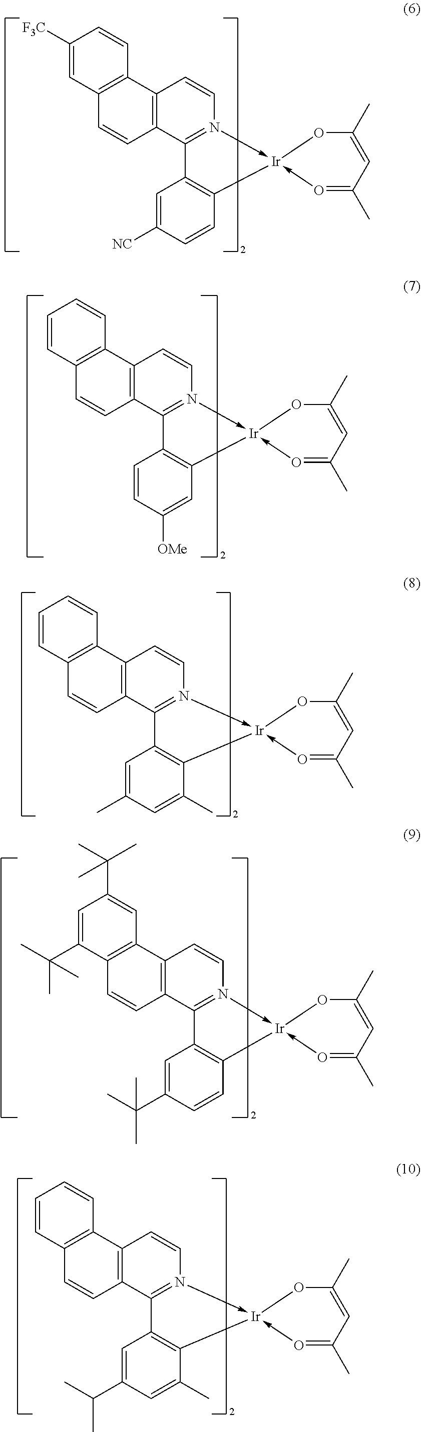

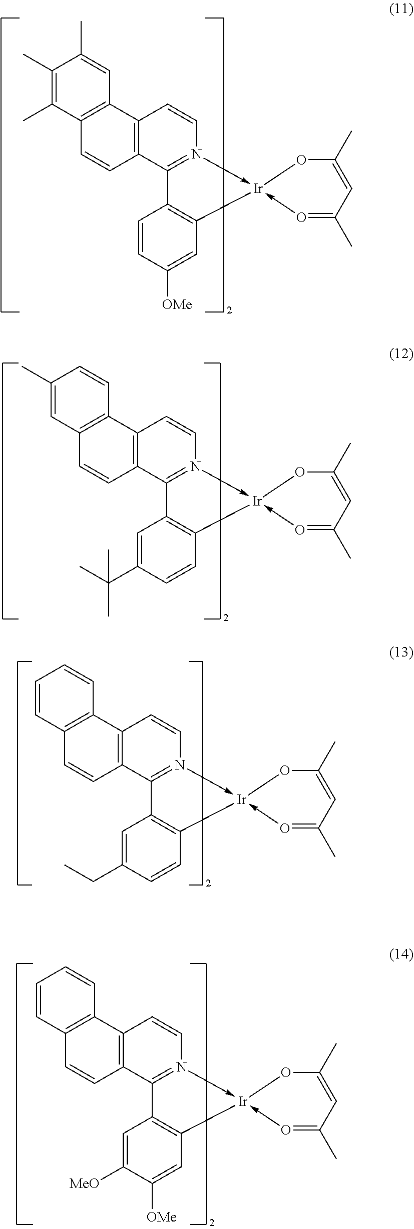

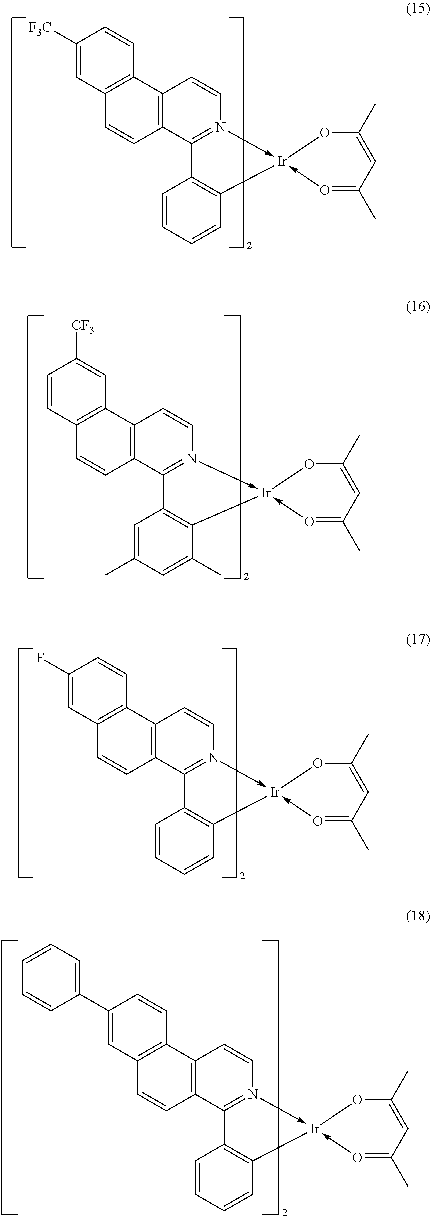

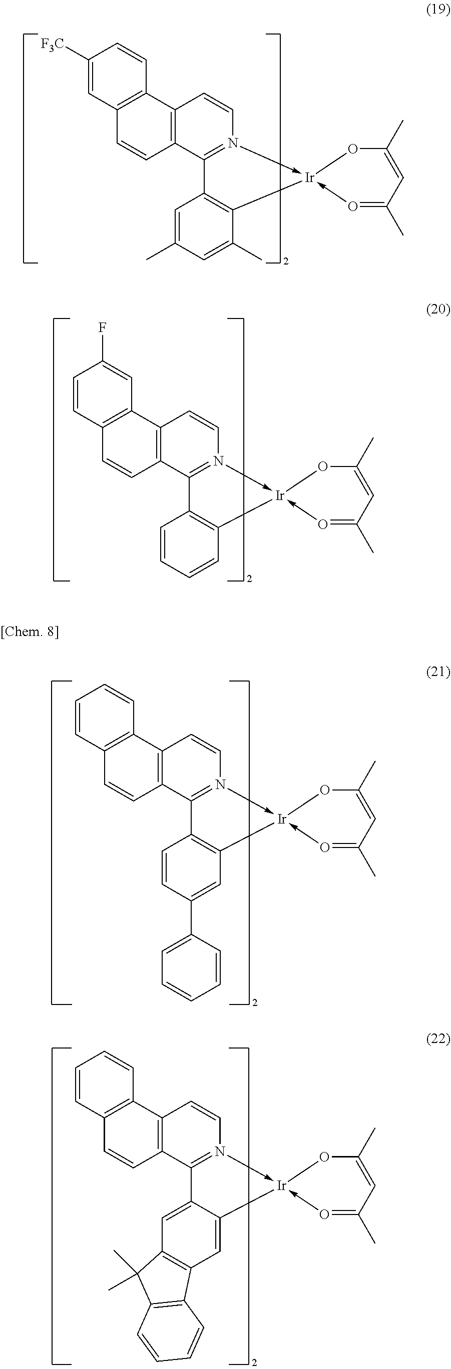

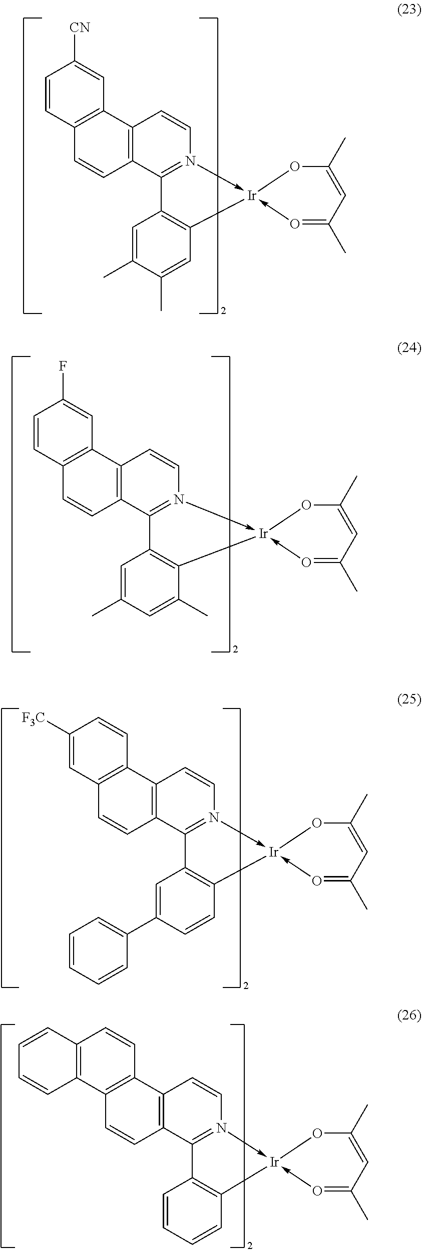

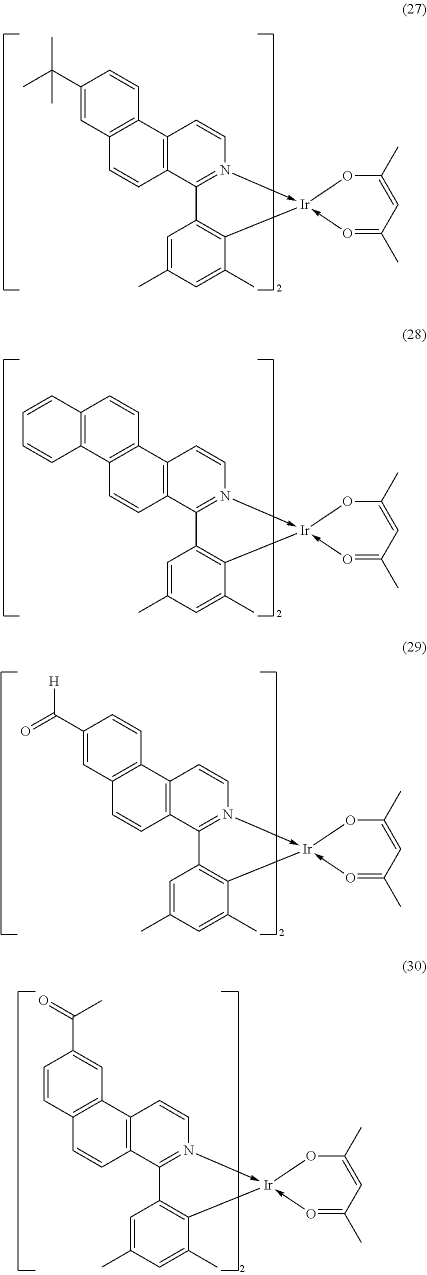

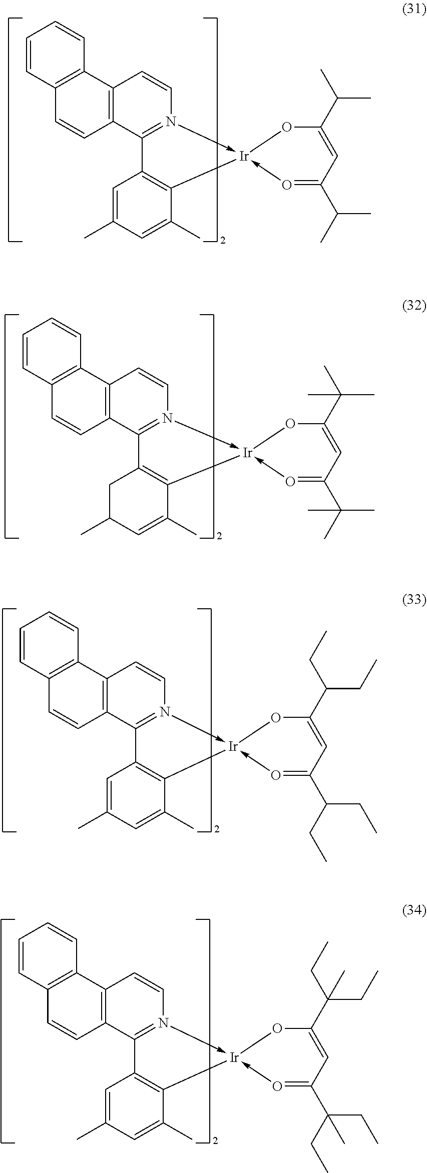

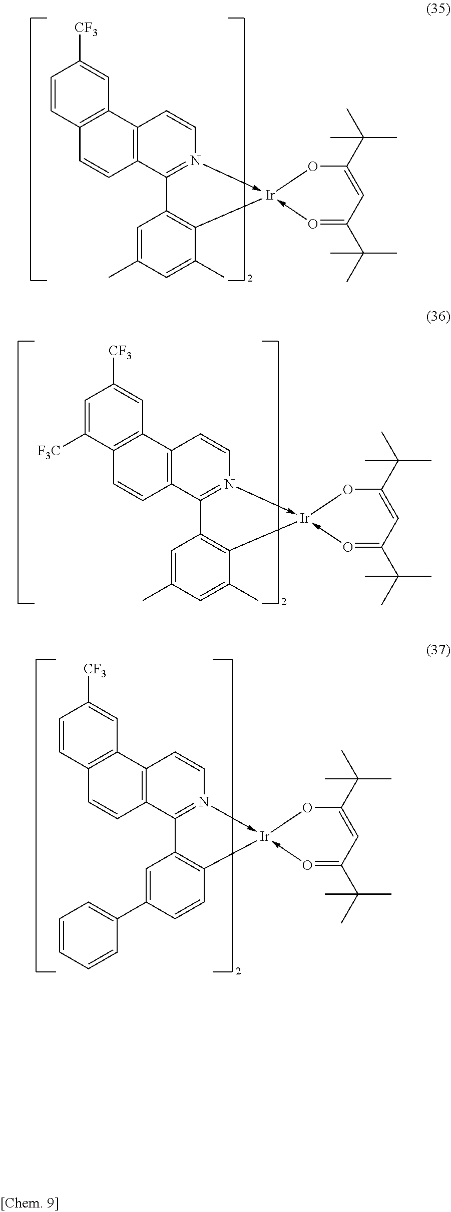

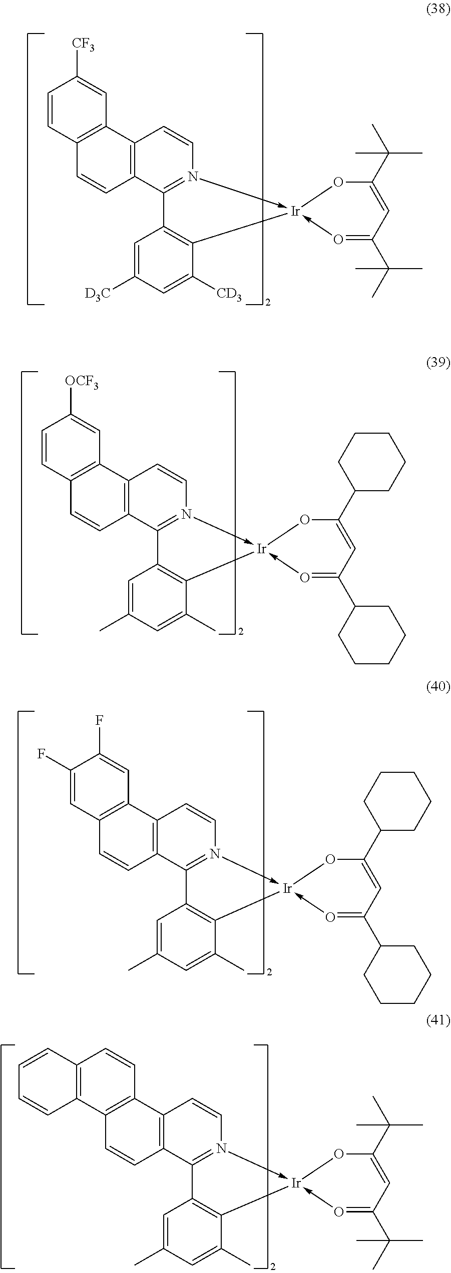

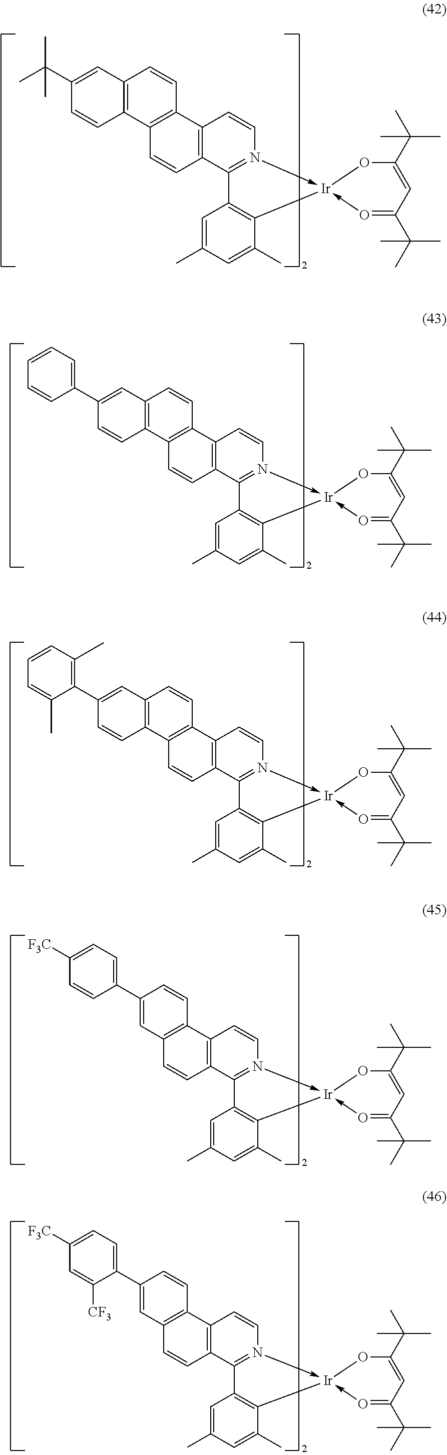

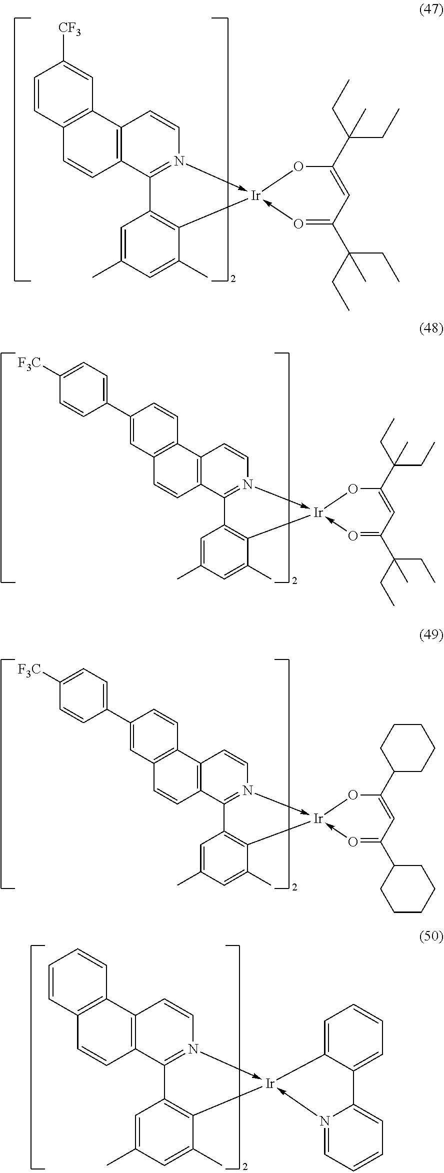

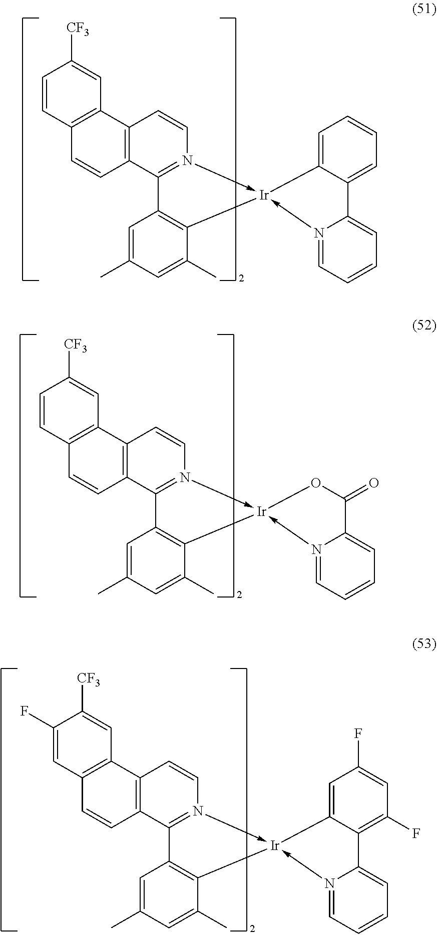

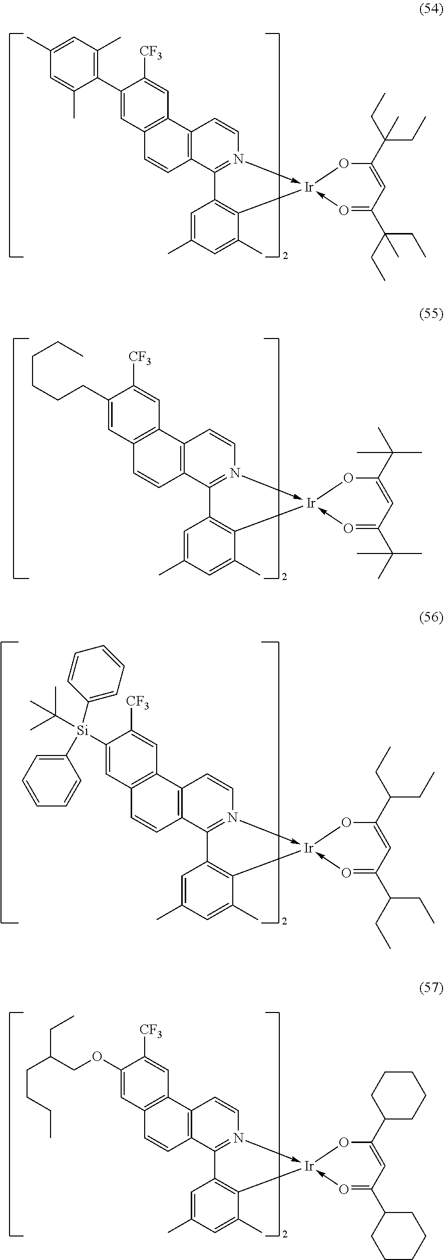

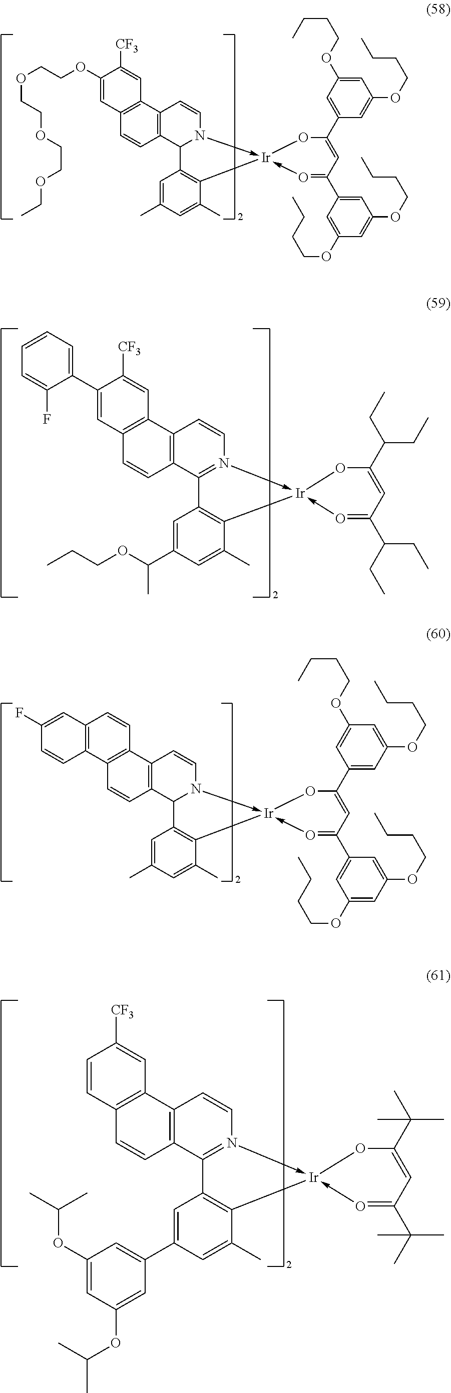

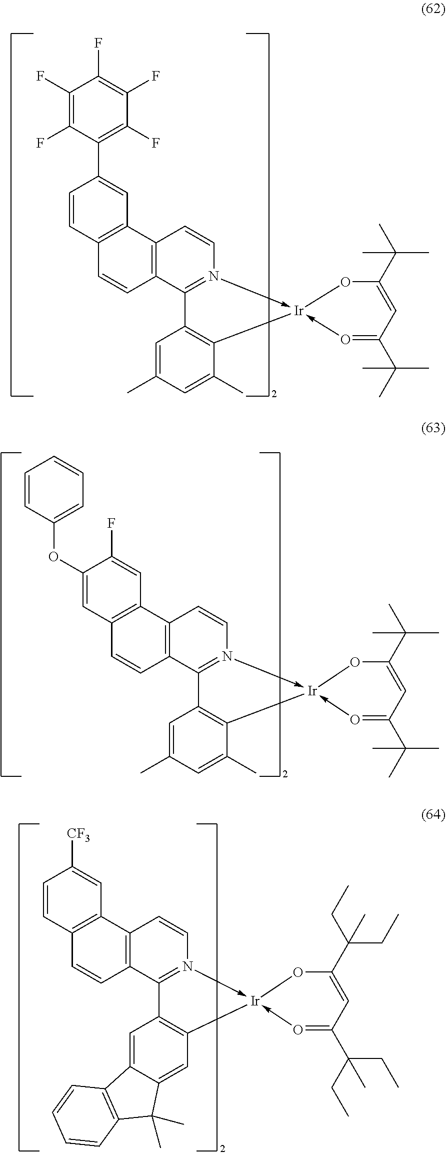

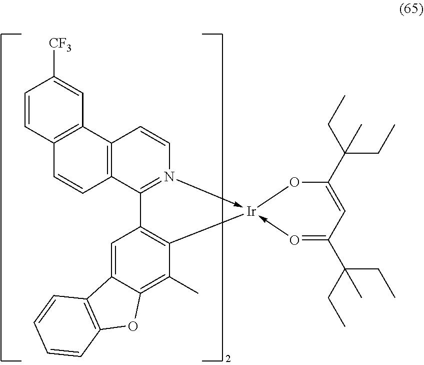

The organometallic complex content (ppm) of the light emitting composition is preferably 1 ppm or more and 3,000 ppm or less based on the total mass of the light emitting composition. The organometallic complex content (ppm) of the light emitting composition is preferably 0.001 times or more and 0.20 times or less by mass ratio based on the total of the fluorene oligomer content (ppm) and the polymer host material content (ppm). A mass ratio in the above range results in efficient energy transfer from a host and less aggregation of the organometallic complex. This can further increase the emission quantum yield of dopant emission and more effectively reduce the emission quantum yield of a host with respect to a dopant.

### (Fluorene Oligomer)

The light emitting composition contains a fluorene oligomer that contains a unit represented by the following general formula (6) and that has a number of repetitions of the unit of 6 or more and 14 or less. The term “fluorene oligomer”, as used herein, refers to a compound with a weight-average molecular weight in the range of 1,000 to 10,000. The fluorene oligomer typically does not have a molecular weight distribution. Such a fluorene oligomer can be purified by a purification method, such as column chromatography or gel permeation chromatography. The fluorene oligomer used in the present invention contains a fluorene unit represented by the general formula (6) and is chemically, thermally, and electrochemically stable. The fluorene oligomer can improve the emission quantum yield of dopant emission and therefore also has a function as a host material by itself.

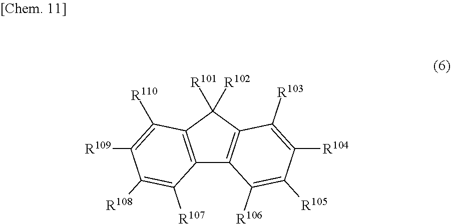

(In the general formula (6), R¹⁰¹ and R¹⁰² each independently denote a hydrogen atom, a deuterium atom, a halogen atom, an alkyl group, a cycloalkyl group, an alkoxy group, an aryloxy group, or a heteroaryloxy group, and a plurality of units represented by the general formula (6) are bonded together at any one of R¹⁰³ to R¹⁰⁶ and any one of R¹⁰⁷ to R¹¹⁰. R¹⁰³ to R¹¹⁰ that are not bonded to an adjacent molecular unit of the general formula (6) each independently denote a hydrogen atom, a deuterium atom, a halogen atom, an alkyl group, an alkoxy group, an aryl group, a heteroaryl group, an aryloxy group, a heteroaryloxy group, or an amino group.) (In the general formula (6), R¹⁰¹ and R¹⁰² each independently denote a hydrogen atom, a deuterium atom, a halogen atom, an alkyl group, a cycloalkyl group, an alkoxy group, an aryloxy group, or a heteroaryloxy group, and a plurality of units represented by the general formula (6) are bonded together at any one of R¹⁰³ to R¹⁰⁶ and any one of R¹⁰⁷ to R¹¹⁰. The halogen atom, the alkyl group, the cycloalkyl group, the alkoxy group, the aryloxy group, and the heteroaryloxy group may be the same as those described for the organometallic complex.

R¹⁰³ to R¹¹⁰ that are not bonded to an adjacent molecular unit of the general formula (6) each independently denote a hydrogen atom, a deuterium atom, a halogen atom, an alkyl group, a cycloalkyl group, an alkoxy group, an aryl group, a heteroaryl group, an aryloxy group, a heteroaryloxy group, or an amino group. The halogen atom, the alkyl group, the cycloalkyl group, the alkoxy group, the aryl group, the heteroaryl group, the aryloxy group, and the heteroaryloxy group may be the same as those described for the organometallic complex. The amino group may be a substituted amino group or an unsubstituted amino group. The substituent of the substituted amino group may be an alkyl group with 1 to 8 carbon atoms, an aryl group with 6 to 10 carbon atoms, or the like. More specifically, the substituted amino group may be a dialkylamino group, an alkylarylamino group, a diarylamino group, or the like. Specific examples thereof include a dimethylamino group, a diisopropylamino group, an ethylphenylamino group, a diphenylamino group, a morpholino group, and the like.

Specific examples of the fluorene oligomer are described below. As a matter of course, the present invention is not limited to the specific examples and includes those represented by the general formula (1) and the general formula (2). The fluorene oligomer is preferably at least one of the following compounds (101) to (118). These are fluorene oligomers composed only of a unit represented by the general formula (6). These compounds can be used to further improve the emission quantum yield of dopant emission and more effectively reduce the emission quantum yield of a host with respect to a dopant.

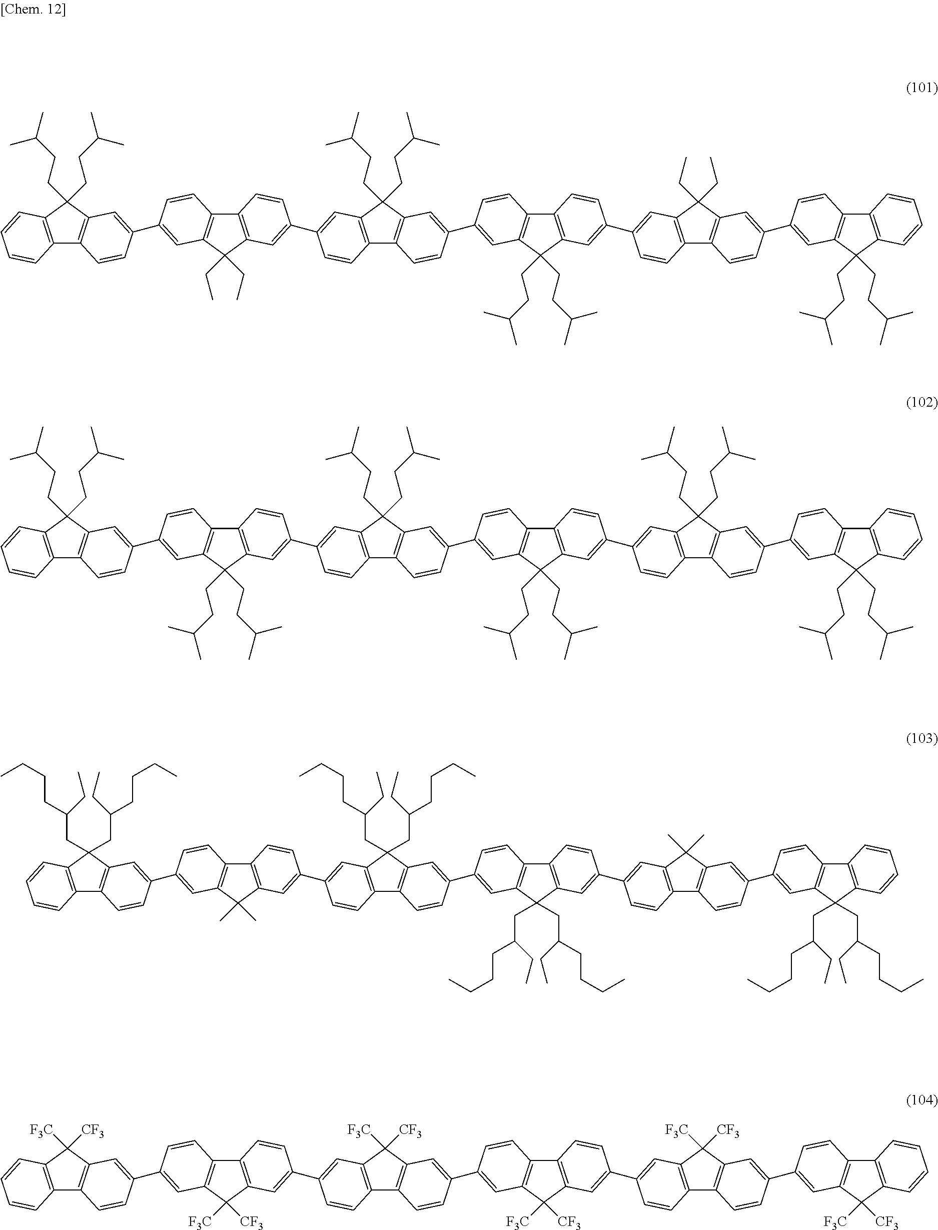

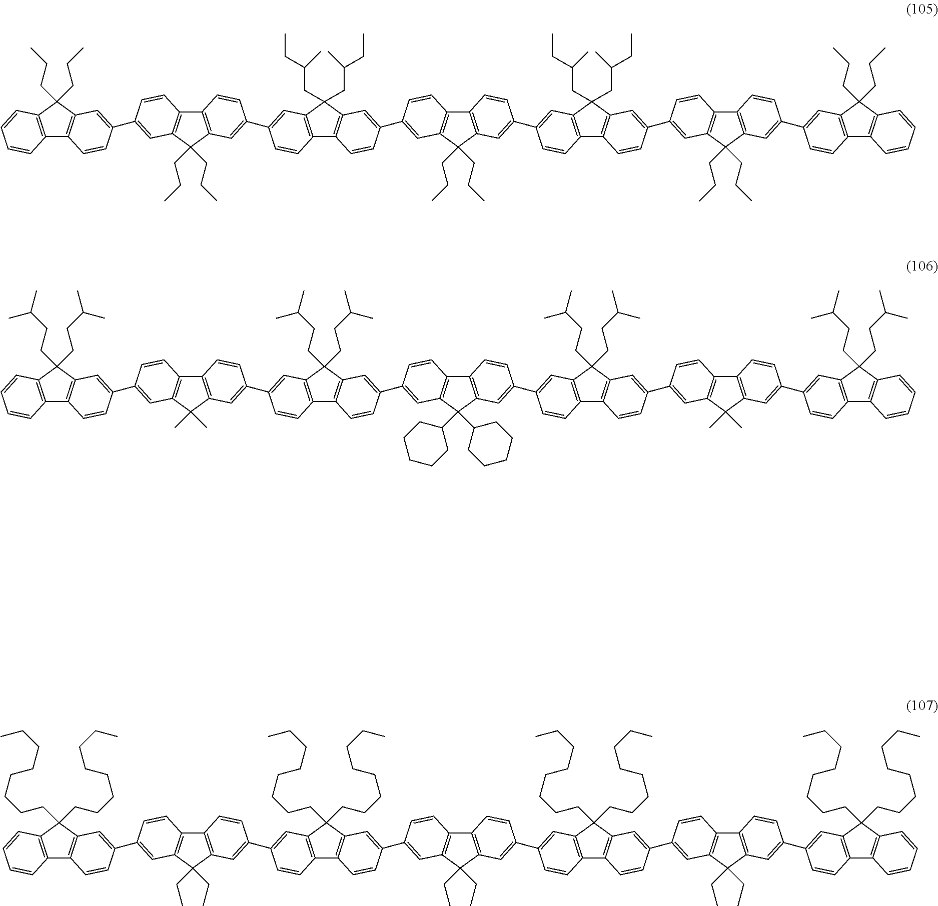

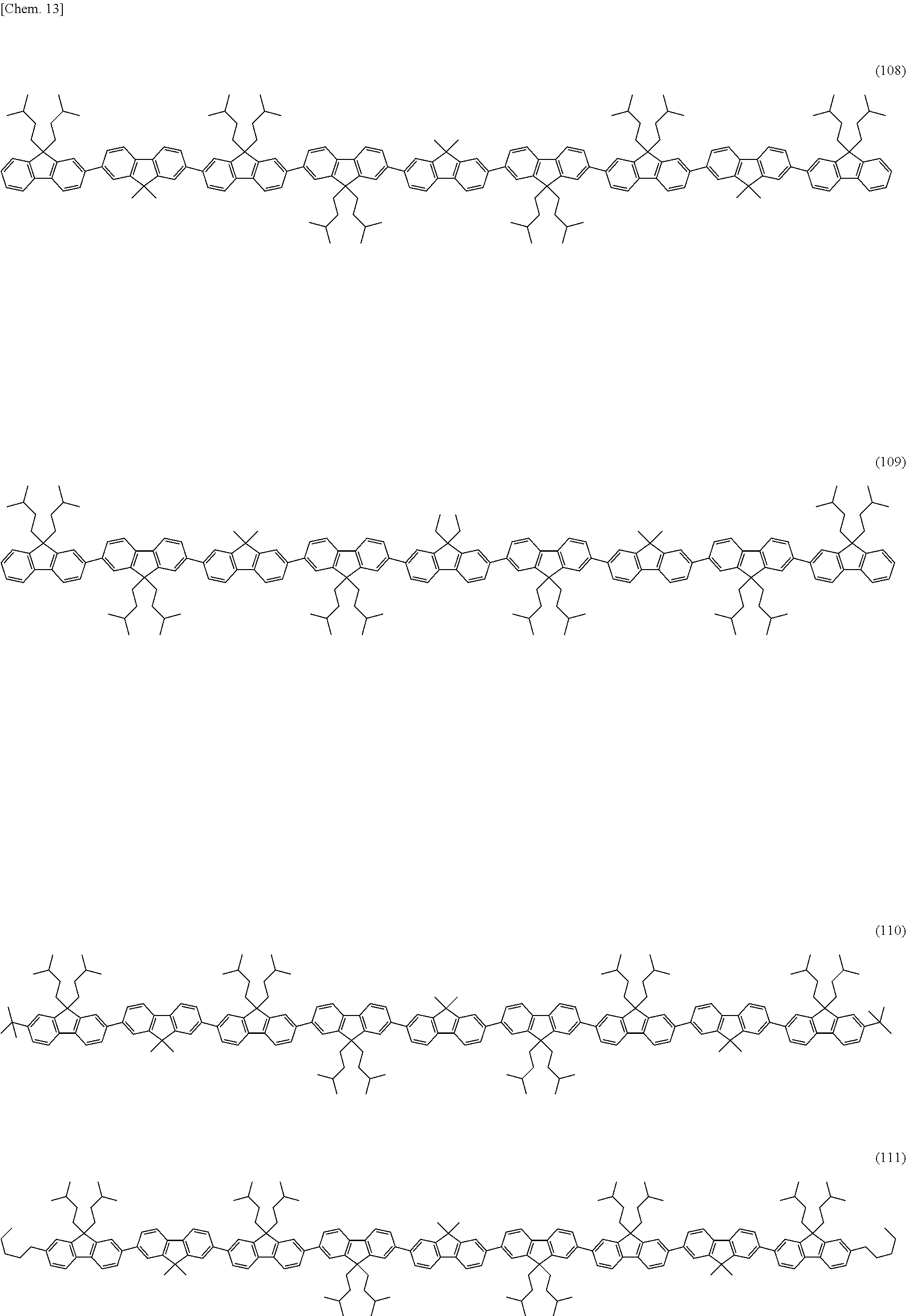

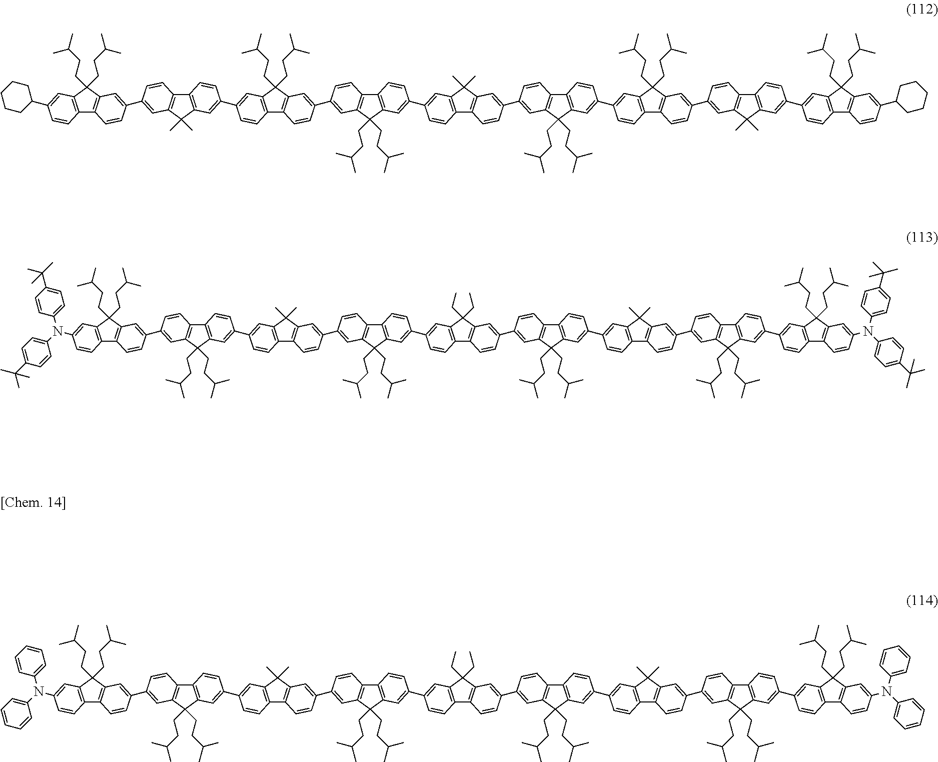

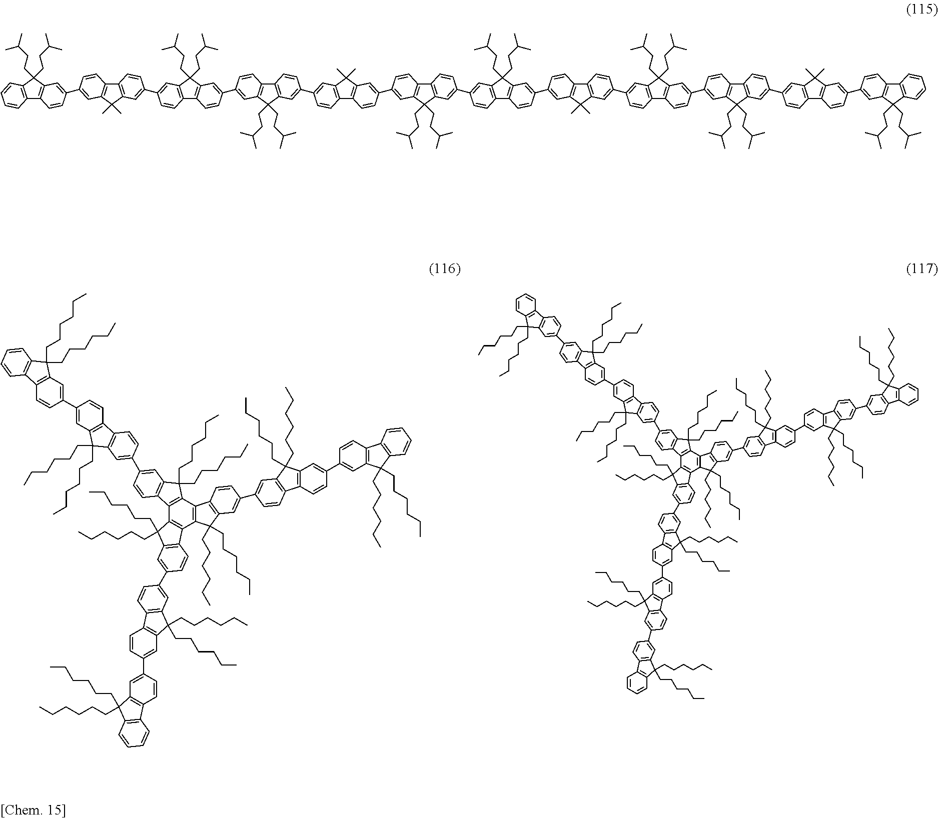

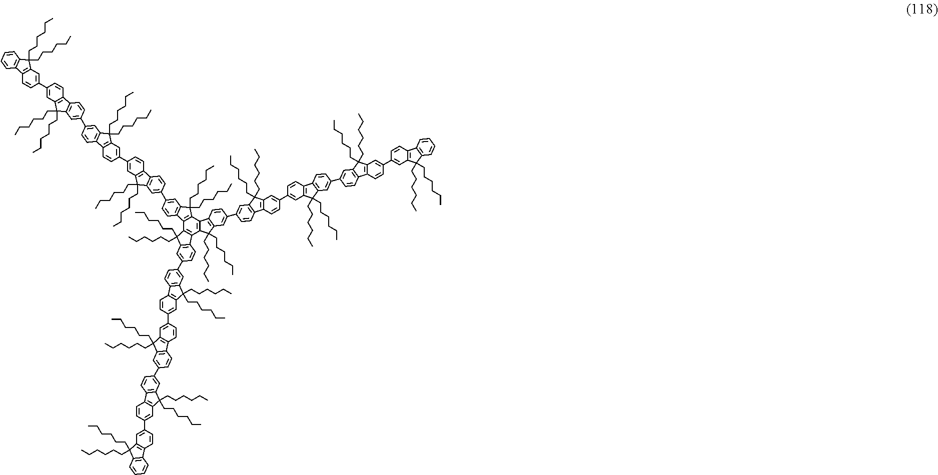

The fluorene oligomer content (ppm) of the light emitting composition is preferably 100 ppm or more and 10,000 ppm or less based on the total mass of the light emitting composition. The fluorene oligomer content (ppm) of the light emitting composition is preferably 0.10 times or more and 0.95 times or less by mass ratio based on the total of the fluorene oligomer content (ppm) and the polymer host material content (ppm). A mass ratio in the above range results in efficient suppression of the aggregation of a polymer host material, efficient mediation of energy transfer, and therefore a more effective reduction in the emission quantum yield of a host with respect to a dopant.

### (Polymer Host Material)

The light emitting composition contains a polymer host material. The polymer host material is preferably a material with a function as a host and, more specifically, can be a known material. The polymer host material in the present description refers to a material with a weight-average molecular weight of 20,000 or more. The polymer host material preferably has a weight-average molecular weight of 3,000,000 or less, more preferably 2,000, 000 or less. The weight-average molecular weight in the present description is a polystyrene equivalent value measured by gel permeation chromatography.

The polymer host material may be conjugated or unconjugated. The conjugated polymeric material is, for example, polyfluorene, poly(phenylene vinylene), a fluorene-carbazole copolymer, a fluorene-diphenylamine copolymer, a fluorene-thiophene copolymer, a fluorene-vinylene copolymer, a derivative thereof, or the like. The unconjugated polymeric material is, for example, polystyrene, polyvinylcarbazole, a derivative thereof, or the like. The polymer host materials may be used alone or in combination.

The polymer host material preferably has charge transport properties and is more preferably a polymer host material with hole transport properties. In particular, the polymer host material is preferably a compound represented by the following general formula (7). This compound is a polyvinylcarbazole derivative and is preferred not only from the perspective of the emission quantum yield of dopant emission and the emission quantum yield of a host with respect to a dopant but also from the perspective of thermal stability.

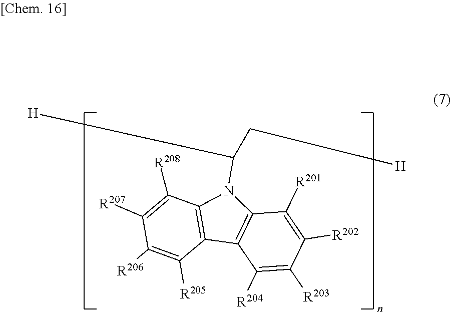

(In the general formula (7), R²⁰¹ to R²⁰⁸ each independently denote a hydrogen atom, a deuterium atom, a halogen atom, an alkyl group, a cycloalkyl group, an alkoxy group, an aryl group, a heteroaryl group, an aryloxy group, or a heteroaryloxy group. n is 50 or more and 10,000 or less.)

In the general formula (7), R²⁰¹ to R²⁰⁸ each independently denote a hydrogen atom, a deuterium atom, a halogen atom, an alkyl group, a cycloalkyl group, an alkoxy group, an aryl group, a heteroaryl group, an aryloxy group, or a heteroaryloxy group. The halogen atom, the alkyl group, the cycloalkyl group, the alkoxy group, the aryl group, the heteroaryl group, the aryloxy group, and the heteroaryloxy group may be the same as those described for the organometallic complex.

The polymer host material content (ppm) of the light emitting composition is preferably 100 ppm or more and 10,000 ppm or less based on the total mass of the light emitting composition.

### (Additive Agent)

In addition to the various materials described above, if necessary, the light emitting composition can contain various additive agents, such as a charge transport material, a resin, a plasticizer, an antioxidant, and an ultraviolet absorber. Among these, a resin or a charge transport material (for example, an electron transport material) is preferably contained. The resin is preferably a resin as a binder. Specific examples thereof include a polyvinylcarbazole resin, a polycarbonate resin, a polyester resin, an ABS resin, an acrylic resin, a polyimide resin, a phenolic resin, an epoxy resin, a silicone resin, a urea resin, and the like. The resin may be a homopolymer or a copolymer, and one or two or more resins can be used. The electron transport material may be a known material. For example, 1,3-bis [2-(4-tert-butylphenyl)-1,3,4-oxadiazo-5-yl]benzene or the like may be mentioned. The electron transport material may also be a commercially available product (for example, trade name “OXD-7”, manufactured by Luminescence Technology) or the like. The electron transport material content (ppm) of the light emitting composition is preferably 10 ppm or more and 5,000 ppm or less based on the total mass of the light emitting composition.

### (Liquid Medium)

The light emitting composition may be a liquid. A liquid light emitting composition contains a liquid medium. The liquid medium may be any liquid medium that can dissolve or disperse an organometallic complex, a fluorene oligomer, and a polymer host material. In particular, an organic solvent with a boiling point of 70° C. or more and 300° C. or less at 1 atm is preferably used. The organic solvent may be water-soluble or water-miscible. The amount (% by mass) of the organic solvent as a liquid medium in a liquid light emitting composition is preferably 90.0% by mass or more and 99.5% by mass or less based on the total mass of the light emitting composition.

More specifically, the organic solvent may be an aromatic hydrocarbon compound, such as toluene, o-xylene, p-xylene, mesitylene, chlorobenzene, o-dichlorobenzene, anisole, or phenylcyclohexane; an alkyl halide, such as dichloromethane or chloroform; an ether, such as diethyl ether, dibutyl ether, tetrahydrofuran, 2-methyltetrahydrofuran, 1,4-dioxane, or diethylene glycol dimethyl ether; a ketone, such as dimethoxyethane, cyclopentanone, cyclohexanone, or methyl ethyl ketone; an ester, such as ethyl acetate, butyl acetate, or methyl benzoate; an amide compound, such as dimethylformamide or dimethylacetamide; a cyclic amide compound (lactam), such as N-methylpyrrolidone or dimethylimidazolidinone; or the like. Among these, a ketone is preferred. The organic solvent can be used to adjust the compatibility of various materials in the light emitting composition, various characteristics, such as the viscosity and surface tension of the liquid, and the like. The organic solvents may be used alone or in combination.

### <Organic Light Emitting Device>

An organic light emitting device includes an insulating layer, a first electrode, an organic compound layer, and a second electrode stacked in this order on a substrate. A protective layer, a color filter, and the like may be provided on the second electrode (in the direction opposite to the substrate). When a color filter is provided, a planarization layer may be provided between a protective layer and the color filter. One of the first electrode and the second electrode is a positive electrode, and the other is a negative electrode.

### (Substrate)

The substrate may be formed of quartz, glass, silicon, a resin, a metal, or the like. A switching element, such as a transistor, wiring, or the like may be provided on the substrate, and an insulating layer may be provided thereon. The insulating layer can be formed of any material that can form a contact hole to secure electrical connection between the positive electrode and wiring and that is insulated from wiring not to be connected. More specifically, the insulating layer may be formed of a resin, such as a polyimide, a silicon compound, such as silicon oxide or silicon nitride, or the like.

### (Electrode)

An organic light emitting device is provided with a pair of electrodes. The pair of electrodes are a positive electrode and a negative electrode. When a voltage is applied in a direction in which the organic light emitting device emits light, an electrode with a high electric potential is a positive electrode, and the other electrode is a negative electrode. In other words, the electrode that supplies a hole to the light emitting layer is a positive electrode, and the electrode that supplies an electron to the light emitting layer is a negative electrode.

A constituent material of the positive electrode preferably has a large work function. Examples thereof include a metal, such as gold, platinum, silver, copper, nickel, palladium, cobalt, selenium, vanadium, or tungsten; a metal oxide, such as tin oxide, zinc oxide, indium oxide, indium tin oxide (ITO), or indium zinc oxide; a mixture or alloy thereof; an electrically conductive polymer, such as polyaniline, polypyrrole, or polythiophene; or the like. The constituent materials of the electrodes may be used alone or in combination. The positive electrode may be composed of one or two or more layers.

A constituent material of the positive electrode used as a reflective electrode is, for example, a metal, such as chromium, aluminum, silver, titanium, tungsten, or molybdenum; an alloy or laminate thereof; or the like. A constituent material of the positive electrode used as a transparent electrode may be an oxide, such as indium tin oxide (ITO) or indium zinc oxide. The positive electrode may be formed by photolithography.

On the other hand, a constituent material of the negative electrode preferably has a small work function. Examples thereof include an alkali metal, such as lithium; an alkaline-earth metal, such as calcium; another metal, such as aluminum, titanium, manganese, silver, lead, or chromium; or an oxide, mixture, or alloy thereof. The alloy is, for example, magnesium-silver, aluminum-lithium, aluminum-magnesium, silver-copper, zinc-silver, or the like. It may be a metal oxide, such as indium tin oxide (ITO). The constituent materials of the electrodes may be used alone or in combination. The negative electrode may be composed of one or two or more layers. In particular, silver is preferably used, and a silver alloy is more preferably used to suppress the aggregation of silver. As long as the aggregation of silver can be suppressed, the alloy may have any ratio. For example, the ratio may be approximately 1:1.

The negative electrode may be a top emission element using an electrically conductive oxide layer of indium tin oxide (ITO) or the like or may be a bottom emission element using a reflective electrode of aluminum (Al) or the like. The negative electrode may also be formed by photolithography. In particular, a method for forming the negative electrode is preferably a sputtering method (direct current or alternating current). This is because a film formed by the sputtering method has good coverage and easily reduces resistance.

### (Protective Layer)

A protective layer can be provided on the negative electrode. For example, a glass sheet with a moisture absorbent layer can be attached to the negative electrode to suppress the entry of water or the like into the organic compound layer and to reduce the occurrence of display defects. Furthermore, a passivation film of silicon nitride or the like may be provided on the negative electrode to suppress the entry of water or the like into the organic compound layer. The protective layer can be formed by a chemical vapor deposition method (CVD method) or the like. The film formation by the chemical vapor deposition method may be followed by an atomic layer deposition method (ALD method) to form a protective layer composed of two layers. For example, after the negative electrode is formed, while the vacuum is maintained, a silicon nitride film can be formed as a protective layer by a CVD method in another chamber. The protective layer preferably has a thickness of 1 μm or more and 10 μm or less.

### (Color Filter)

A color filter can be provided on a protective layer. For example, a color filter that matches the size of the organic light emitting device may be provided on another substrate and may be bonded to the substrate on which the organic light emitting device is provided, or a color filter may be patterned by photolithography. The color filter can be made of a polymeric material or the like.

### (Planarization Layer)

A planarization layer can be provided between a color filter and a protective layer. A constituent material of the planarization layer may be an organic compound, preferably a high-molecular-weight organic compound. The planarization layer may be provided on both sides of a color filter and, in such a case, the constituent material of each planarization layer may be the same or different. A constituent material of the planarization layer may be a resin, such as a polyvinylcarbazole resin, a polycarbonate resin, a polyester resin, an ABS resin, an acrylic resin, a polyimide resin, a phenolic resin, an epoxy resin, a silicone resin, or a urea resin. The ABS resin is composed of three monomers: acrylonitrile, butadiene, and styrene.

### (Opposite Substrate)

An opposite substrate can be provided on a planarization layer. The opposite substrate is provided to face the substrate and is therefore referred to as an opposite substrate. A constituent material of the opposite substrate may be the same as the constituent material of the substrate.

### (Organic Compound Layer)

An organic light emitting device includes at least a first electrode and a second electrode, which are a pair of electrodes, and an organic compound layer, which is a light emitting layer between the first electrode and the second electrode. The organic compound layer may be a single layer or a laminate of a plurality of layers, provided that it includes a light emitting layer.

When the organic compound layer is a laminate of a plurality of layers, at least one layer of the organic compound layer is a light emitting layer. In addition to the light emitting layer, the organic compound layer may include a hole injection layer, a hole transport layer, an electron-blocking layer, a hole/exciton-blocking layer, an electron transport layer, an electron injection layer, and/or the like. The light emitting layer may be a single layer or a laminate of a plurality of layers. The hole transport layer and the electron transport layer are also referred to as charge transport layers.

At least one layer of an organic compound layer of an organic light emitting device contains the organometallic complex described above. More specifically, the organometallic complex is preferably contained in at least one of a hole injection layer, a hole transport layer, an electron-blocking layer, a light emitting layer, a hole/exciton-blocking layer, an electron transport layer, an electron injection layer, and the like. Among them, it is preferably contained in the light emitting layer.

The first electrode, the light emitting layer, and a transport layer disposed between the first electrode and the light emitting layer integrally have a function of transporting an electric charge and can be collectively treated as a first charge transport layer. Likewise, the second electrode, the light emitting layer, and a transport layer disposed between the second electrode and the light emitting layer integrally have a function of transporting an electric charge and can be collectively treated as a second charge transport layer. Thus, one surface of the light emitting layer is in contact with the first charge transport layer, and the other surface is in contact with the second charge transport layer.

When the organometallic complex is contained in the light emitting layer, the light emitting layer may be formed of the organometallic complex and does not necessarily contain another component. Thus, the light emitting layer may be a layer formed only of the organometallic complex. The light emitting layer may contain a first organic compound in addition to the organometallic complex. In such a case, the lowest excited triplet energy of the first organic compound is preferably equal to or higher than the lowest excited triplet energy of the organometallic complex and equal to or lower than the lowest excited triplet energy of a fluorene oligomer. The light emitting layer may contain the organometallic complex, a first organometallic compound, and a second organic compound different from the first organic compound. The lowest excited triplet energy of the second organic compound is preferably equal to or higher than the lowest excited triplet energy of the organometallic complex and equal to or lower than the lowest excited triplet energy of the first organic compound. When the light emitting layer contains the first organic compound and the second organic compound, the first organic compound may be a host of the light emitting layer, and the second organic compound may be an assist material. The organometallic complex may be a guest or a dopant.

The host is the component with the highest mass content among the constituent materials of the light emitting layer. The guest or dopant is a component with a mass content lower than that of the host in the constituent materials of the light emitting layer and is a component responsible for main light emission. The assist material is a component with a mass content lower than that of the host in the constituent materials of the light emitting layer and is a component that assists the light emission of the guest. The assist material is also referred to as a second host.

When the organometallic complex is used as a guest of the light emitting layer, the guest content (% by mass) is preferably 0.01% by mass or more and 20.0% by mass or less, more preferably 0.1% by mass or more and 10.0% by mass or less, based on the total mass of the light emitting layer. The total mass of the light emitting layer refers to the total amount of the components constituting the light emitting layer.

The lowest excited triplet energy of the first charge transport layer is preferably higher than the lowest excited triplet energy of each of the polymer host material and the fluorene oligomer. Furthermore, the lowest excited triplet energy of the second charge transport layer is preferably higher than the lowest excited triplet energy of each of the polymer host material and the fluorene oligomer. The lowest excited triplet energy of a charge transport layer can be estimated by the lowest excited triplet energy of a constituent material of the layer. For a charge transport layer formed of a plurality of materials, the lowest excited triplet energy may be considered as the lowest excited triplet energy of a compound with the highest mass content.

The layers constituting an organic light emitting device each independently preferably have a thickness of 1 nm or more and 10,000 nm or less (10 μm or less). In particular, from the perspective of good emission properties, the thickness is preferably 10 nm or more and 100 nm or less.

### <Method for Manufacturing Organic Light Emitting Device>

A method for manufacturing an organic light emitting device with an organic compound layer (such as a hole injection layer, a hole transport layer, an electron-blocking layer, a light emitting layer, a hole-blocking layer, an electron transport layer, or an electron injection layer) is described below. The organic light emitting device is manufactured by a manufacturing method including applying a light emitting composition to a base material to form an organic compound layer.

A method for forming the organic compound layer is, for example, a dry process or a wet process. The dry process is, for example, a vacuum deposition method, an ionized deposition method, a sputtering method, a plasma method, or the like. The wet process is a method of applying a liquid light emitting composition to a base material by a known method. The method of applying a liquid light emitting composition to a base material is, for example, a known method, including a coating method, such as a spin coating method, a casting method, a gravure coating method, a bar coating method, a roll coating method, a wire bar coating method, a dip coating method, a capillary coating method, or a spray coating method; or a printing method, such as a screen method, a flexographic method, an offset method, or an ink jet method. Among these, it is preferable to use a vacuum deposition method, an ionized deposition method, a spray coating method, or an ink jet method. The above method is suitable from the perspective that an organic light emitting device with a large area can be manufactured. In particular, an ink jet method is preferably used.

After the organic compound layer is formed by the wet process, the liquid medium is preferably dried. The drying conditions can be appropriately determined according to the constituent materials of the organic compound layer and the like. It is preferable to dry in an atmosphere of air or inert gas (nitrogen, argon, or the like). The heating temperature for drying is preferably 100° C. or more and 250° C. or less, more preferably 110° C. or more and 200° C. or less. The heating time for drying is preferably 5 minutes or more and 60 minutes or less. The pressure during heating for drying may be atmospheric pressure (1 atm) or reduced pressure (100 Pa to 0.1 MPa). Various conditions (temperature, pressure, and time) in the drying process may be determined so that the liquid medium can be removed from the organic compound layer and the like.

When the organic compound layer is formed by the wet process using a liquid light emitting composition, it is preferable to appropriately determine the composition. The amount (% by mass) of an organic solvent as a liquid medium in the light emitting composition is preferably 10.0 times or more and 100.0 times or less by mass ratio based on the total amount (% by mass) of the solid components constituting the organic compound layer. The solid components constituting the organic compound layer may be an organometallic complex, a fluorene oligomer, a polymer host material, and the like.

When an organic compound layer is formed by applying a liquid light emitting composition to a base material by an ink jet method, it is preferable to appropriately control the physical properties thereof. The liquid light emitting composition preferably has a surface tension of 15 mN/m or more and 75 mN/m or less, more preferably 25 mN/m or more and 45 mN/m or less, at 25° C. The surface tension of the liquid light emitting composition can be adjusted by appropriately determining the type and amount of organic solvent in the light emitting composition. The liquid light emitting composition preferably has a viscosity of 0.1 mPa·s or more and 20.0 mPa·s or less, more preferably 0.5 mPa·s or more and 10.0 mPa·s or less, at 25° C. Setting the viscosity in the above range can suppress clogging or ejection failure in a liquid ejection head during ejection by an ink jet method.

### <Pixel Circuit>

An organic light emitting apparatus may include a pixel circuit coupled to an organic light emitting device. The pixel circuit is preferably of an active-matrix type, which independently controls the light emission of a plurality of organic light emitting devices. The active-matrix circuit may be voltage programmed or current programmed. A drive circuit has a pixel circuit for each pixel. The pixel circuit may further include a transistor for controlling the luminous brightness of the organic light emitting device, a transistor for controlling light emission timing, a capacitor for holding the gate voltage of the transistor for controlling the luminous brightness, and a transistor for ground connection without through the organic light emitting device.

The organic light emitting apparatus includes a display region and a peripheral region around the display region. The display region includes a pixel circuit, and the peripheral region includes a display control circuit. The mobility of a transistor constituting the pixel circuit may be smaller than the mobility of a transistor constituting the display control circuit. The gradient of the current-voltage characteristics of a transistor constituting the pixel circuit may be smaller than the gradient of the current-voltage characteristics of a transistor constituting the display control circuit. The gradient of the current-voltage characteristics can be determined by so-called Vg-Ig characteristics. A transistor constituting the pixel circuit is a transistor coupled to an organic light emitting device.

### <Pixel>

An organic light emitting apparatus has a plurality of pixels. Each pixel has subpixels that emit light of different colors. The subpixels each independently have red (R), green (G), and blue (B) emission colors. In each pixel, a region also referred to as a pixel aperture emits light. The pixel aperture is preferably 15 μm or less and preferably 5 μm or more. The pixel aperture can be, for example, 11.0 μm, 9.5 μm, 7.4 μm, 6.4 μm, or the like. The distance between the subpixels is preferably 10 μm or less. The distance between the subpixels can be, for example, 8.0 μm, 7.4 μm, or 6.4 μm.

The pixels can have a known planar arrangement. Specific examples thereof include a stripe arrangement, a delta arrangement, a PenTile arrangement, a Bayer arrangement, and the like. The subpixels can have a known planar shape. Specific examples thereof include a tetragon, such as a rectangle or a rhombus, a hexagon, and the like. Regarding the planar shape of the subpixels, a shape that approximates a rectangle is treated as a rectangle, even if it is not perfectly rectangular. The planar shape of the subpixels and the pixel array can be used in combination.

### <Applications of Organic Light Emitting Device>

An organic light emitting device can be used as a constituent of a display apparatus or a lighting apparatus. Other applications include an exposure light source for an electrophotographic image-recording apparatus, a backlight for a liquid crystal display, and a light emitting apparatus with a color filter in a white light source.

The display apparatus includes an image input unit that inputs image information from an area CCD, a linear CCD, a memory card, or the like, and an information processing unit that processes the input information. CCD stands for a charge-coupled device. The display apparatus may be an image information processor that displays an input image on a display unit. A display unit of an imaging apparatus or an ink jet recording apparatus may have a touch panel function. A method of driving the touch panel function is specifically an infrared method, a capacitance method, a resistive film method, an electromagnetic induction method, or the like. Furthermore, the display apparatus may be used for a display unit of a so-called composite recording apparatus.

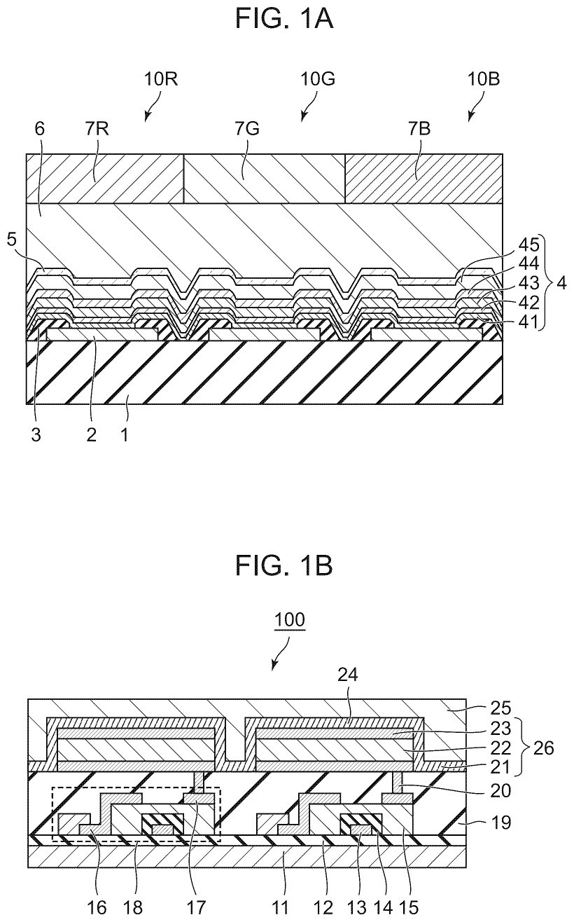

Next, a display apparatus is described with reference to the accompanying drawings. FIG. 1A is a schematic cross-sectional view of an example of a pixel constituting a display apparatus. The pixel has subpixels 10. The subpixels 10 are divided into 10R, 10G, and 10B according to light emission thereof. The emission color may be distinguished and determined by the wavelength of light emitted from a light emitting layer or may be determined by selective transmission or color conversion of light emitted from the subpixels 10 by a color filter or the like. Each of the subpixels 10 includes, on an interlayer insulating layer 1, a reflective electrode 2 serving as a first electrode, an insulating layer 3 covering the edge of the reflective electrode 2, an organic compound layer 4 covering the first electrode and the insulating layer, a transparent electrode 5, a protective layer 6, and a color filter 7.

In the illustrated direction, a transistor or a capacitive element may be disposed below or inside the interlayer insulating layer 1. The transistor and the first electrode may be electrically connected to each other through a contact hole (not shown) or the like. The insulating layer 3 is also referred to as a bank or a pixel separation film. The insulating layer 3 covers the edge of the first electrode and surrounds the first electrode. A portion not covered with the insulating layer 3 is in contact with the organic compound layer 4 and serves as a light emitting region. The organic compound layer 4 includes a hole injection layer 41, a hole transport layer 42, a first light emitting layer 43, a second light emitting layer 44, and an electron transport layer 45. The second electrode may be any one of a transparent electrode, a reflective electrode, and a semitransparent electrode. The protective layer 6 reduces the penetration of a liquid component, such as water, into the organic compound layer. The protective layer is illustrated as a single layer but may be composed of a plurality of layers. In the case of being composed of a plurality of layers, there may be an inorganic compound layer or an organic compound layer. The color filter 7 is divided into 7R, 7G, and 7B according to the color. The color filter may be formed on a planarizing film (not shown). Furthermore, a resin protective layer (not shown) may be provided on the color filter. Furthermore, the color filter may be formed on the protective layer 6 or may be provided on and then bonded to an opposite substrate, such as a glass substrate.

FIG. 1B is a schematic cross-sectional view of an example of a display apparatus including an organic light emitting device 26 and a transistor coupled to the organic light emitting device 26. The transistor is an example of an active element. The transistor may be a thin-film transistor (TFT). A display apparatus 100 in FIG. 1B includes a substrate 11 formed of glass, silicon, or the like, and an insulating layer 12 provided on the substrate 11. An active element 18, such as the TFT, and a gate electrode 13, a gate-insulating film 14, and a semiconductor layer 15 of the active element are disposed on the insulating layer 12. The TFT 18 is composed of the semiconductor layer 15, a drain electrode 16, and a source electrode 17. An insulating film 19 is provided on the TFT 18. A positive electrode 21 constituting the organic light emitting device and the source electrode 17 are connected via a contact hole 20 provided in the insulating film. Electrical connection between electrodes of the organic light emitting device (the positive electrode and a negative electrode) and the electrodes of the TFT (the source electrode and the drain electrode) is not limited to that illustrated in FIG. 1B. That is, the positive electrode or the negative electrode may be electrically connected to the source electrode or the drain electrode of the TFT.

The organic compound layer 22 in the display apparatus 100 in FIG. 1B is a single layer but may be composed of a plurality of layers. A negative electrode 23 is covered with a first protective layer 24 and a second protective layer 25 for reducing degradation of the organic light emitting device. The display apparatus 100 in FIG. 1B includes a transistor as a switching element but may include another switching element instead thereof.

The transistor used in the display apparatus 100 in FIG. 1B is not limited to a transistor including a single crystal silicon wafer and may also be a thin-film transistor including an active layer on an insulating surface of a substrate. The active layer may be single-crystal silicon, non-single-crystal silicon, such as amorphous silicon or microcrystalline silicon, a non-single-crystal oxide semiconductor, such as indium zinc oxide or indium gallium zinc oxide, or the like.

The transistor in the display apparatus 100 in FIG. 1B may be formed within a substrate, such as a silicon substrate. The phrase “formed within a substrate” means that the substrate, such as a silicon substrate, is processed to form the transistor. Thus, the transistor within the substrate can be considered that the substrate and the transistor are integrally formed.

In the organic light emitting device, the luminous brightness is controlled with the TFT, which is an example of a switching element, and the organic light emitting device is provided in a plurality of planes to display an image at each luminous brightness. The switching element is not limited to the TFT and may be a transistor formed of low-temperature polysilicon or an active-matrix driver formed on a substrate, such as a silicon substrate. On the top or inside of a substrate can also be referred to as within the substrate. Whether a transistor is provided within a substrate or a TFT is used depends on the size of a display unit. For example, for an approximately 0.5-inch display unit, an organic light emitting device can be provided on a silicon substrate.

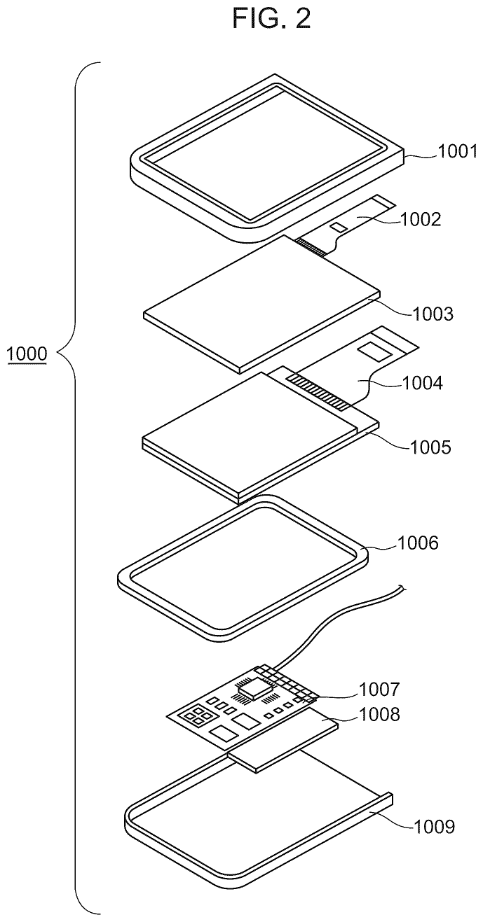

FIG. 2 is a schematic view of an example of a display apparatus. A display apparatus 1000 includes a touch panel 1003, a display panel 1005, a frame 1006, and a circuit substrate 1007 between an upper cover 1001 and a lower cover 1009. Flexible printed circuits (FPCs) 1002 and 1004 are connected to the touch panel 1003 and the display panel 1005. Transistors are printed on the circuit substrate 1007. When the display apparatus is a mobile device, the battery 1008 is provided. The battery 1008 may be provided at another position.

The display apparatus may include color filters of red (R), green (G), and blue (B). In the color filters, red, green, and blue may be arranged in a delta arrangement, a stripe arrangement, or a mosaic arrangement.

The display apparatus can be used for a display unit of a mobile terminal. Such a display apparatus may have both a display function and an operation function. The mobile terminal may be a mobile phone, such as a smartphone, a tablet, a head-mounted display, or the like.

The display apparatus can be used for a display unit of an imaging apparatus that includes an optical unit with a plurality of lenses and an imaging device for receiving light passing through the optical unit. The imaging apparatus may include a display unit for displaying information acquired by the imaging device. The display unit may be a display unit exposed outside from the imaging apparatus or a display unit located in a finder. The imaging apparatus may be a digital camera or a digital camcorder. The imaging apparatus may also be referred to as a photoelectric conversion apparatus.

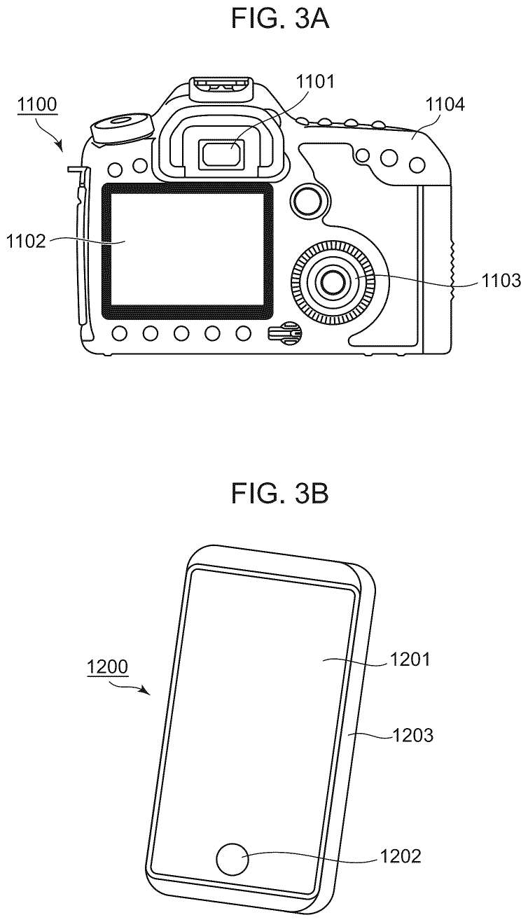

FIG. 3A is a schematic view of an example of an imaging apparatus. An imaging apparatus 1100 includes a viewfinder 1101, a rear display 1102, an operating unit 1103, and a housing 1104. The viewfinder 1101 can be a display apparatus. In such a case, the display apparatus may display environmental information, imaging instructions, and the like as well as an image to be captured. The environmental information may include the intensity of external light, the direction of external light, the travel speed of the photographic subject, the possibility that the photographic subject is shielded by a shielding material, and the like.

The timing suitable for imaging is a short time, and information can therefore preferably be displayed quickly. Since an organic light emitting device has a high response speed, a display apparatus including an organic light emitting device according to the present invention can be suitably applied. The imaging apparatus 1100 includes an optical unit (not shown). The optical unit has a plurality of lenses and focuses an image on an imaging device in the housing 1104. The focus of the lenses can be adjusted by adjusting their relative positions. This operation can also be automatically performed.

FIG. 3B is a schematic view of an example of electronic equipment. Electronic equipment 1200 includes a display unit 1201, an operating unit 1202, and a housing 1203. The housing 1203 includes a circuit, a printed circuit board including a circuit, a battery, a communication unit, and the like. The operating unit 1202 may be a button or a touch panel response unit. The operating unit 1202 may be a biometric recognition unit that recognizes a fingerprint and releases the lock. Electronic equipment with a communication unit may also be referred to as communication equipment. The electronic equipment 1200 may have a lens and an imaging device and thereby further have a camera function. In such a case, an image captured by the camera function is displayed on the display unit 1201. The electronic equipment 1200 may be a smartphone, a notebook computer, or the like.

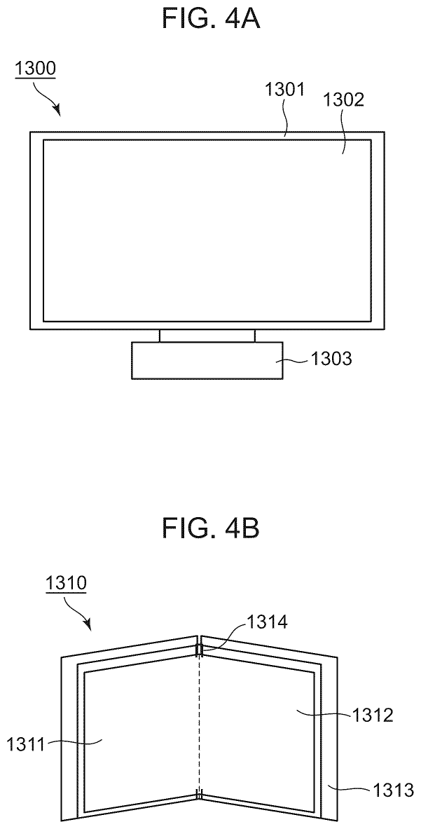

FIGS. 4A and 4B are schematic views of an example of a display apparatus. FIG. 4A illustrates a display apparatus as a monitor of a television set, a personal computer, or the like. The display apparatus 1300 includes a frame 1301, a display unit 1302, and a base for supporting the display unit 1302. The display unit 1302 is a light emitting apparatus. The base 1303 is not limited to that illustrated in FIG. 4A, and the lower side of the frame 1301 may also serve as the base. The frame 1301 and the display unit 1302 may be bent. The radius of curvature thereof is preferably 5,000 mm or more and 6,000 mm or less.

FIG. 4B is a schematic view of another example of the display apparatus. A display apparatus 1310 in FIG. 4B is configured to be foldable and is a so-called foldable display apparatus. The display apparatus 1310 includes a first display unit 1311, a second display unit 1312, a housing 1313, and a bending point 1314. The first display unit 1311 and the second display unit 1312 can be light emitting apparatuses. The first display unit 1311 and the second display unit 1312 may be a single seamless display apparatus. The first display unit 1311 and the second display unit 1312 can be divided at the bending point. The first display unit 1311 and the second display unit 1312 may display different images or may display one image.

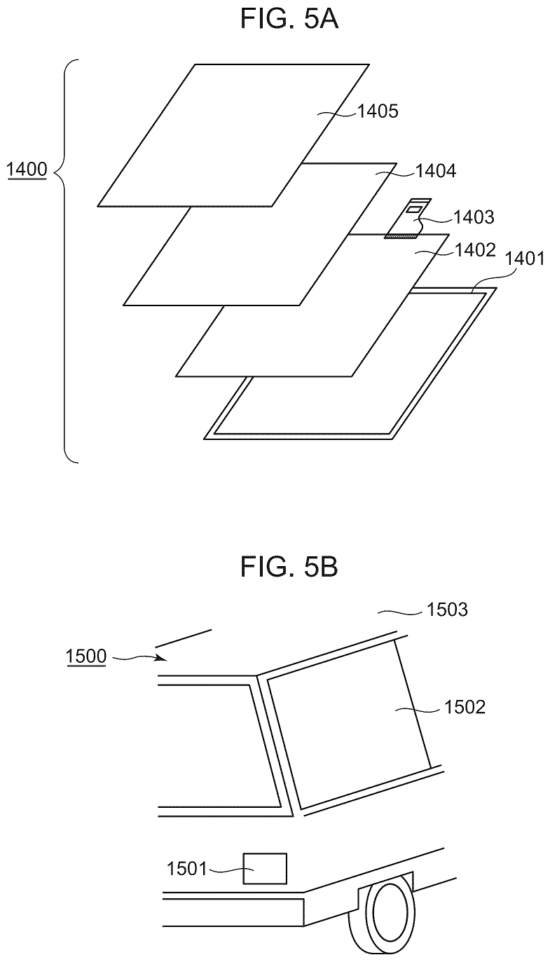

FIG. 5A is a schematic view of an example of a lighting apparatus. A lighting apparatus 1400 includes a housing 1401, a light source 1402, a circuit substrate 1403, an optical filter 1404, and a light-diffusing unit 1405. The light source can be an organic light emitting device. The optical filter may be a filter for improving the color rendering properties of the light source. The light-diffusing unit can effectively diffuse light from the light source and widely spread light as in illumination. The optical filter and the light-diffusing unit may be provided on the light output side of the lighting apparatus. If necessary, a cover may be provided on the outermost side.

The lighting apparatus is, for example, an apparatus that illuminates the interior of a room and includes a light source and a member that transmits light emitted by the light source. The lighting apparatus may emit white light, neutral white light, or light of any color from blue to red. “White” has a color temperature of approximately 4,200 K, and “neutral white” has a color temperature of approximately 5,000 K. The lighting apparatus may have a light control circuit for controlling such light. The lighting apparatus may include an organic light emitting device and a power supply circuit coupled thereto. The power supply circuit is a circuit that converts an AC voltage to a DC voltage. The lighting apparatus may include a light-diffusing unit or a color filter as a member that transmits light emitted by the light source. The lighting apparatus may also include a heat dissipation unit. The heat dissipation unit releases heat from the apparatus to the outside and may be a metal, liquid silicone, or the like with a high specific heat.

FIG. 5B is a schematic view of an automobile as an example of a moving body. The automobile has a taillight as an example of a lamp. An automobile 1500 may have a taillight 1501, which comes on when a brake operation or the like is performed.

The taillight 1501 may have an organic light emitting device. The taillight may include a protective member for protecting the organic light emitting device. Any protective member that has moderately high strength and is transparent can be suitable for the protective member. In particular, the protective member is preferably composed of polycarbonate. The polycarbonate may be mixed with a furandicarboxylic acid derivative, an acrylonitrile derivative, or the like.

The automobile 1500 may have a body 1503 and a window 1502 on the body 1503. The window may be a transparent display unless it is not a window for checking the front and rear of the automobile. The transparent display may include an organic light emitting device. In such a case, a constituent material, such as an electrode of an organic light emitting device, is composed of a transparent member.

a constituent material, such as an electrode of an organic light emitting device

The moving body may be a ship, an aircraft, a drone, or the like. The moving body may include a body and a lamp provided on the body. The lamp may emit light to indicate the position of the body. The lamp has an organic light emitting device.

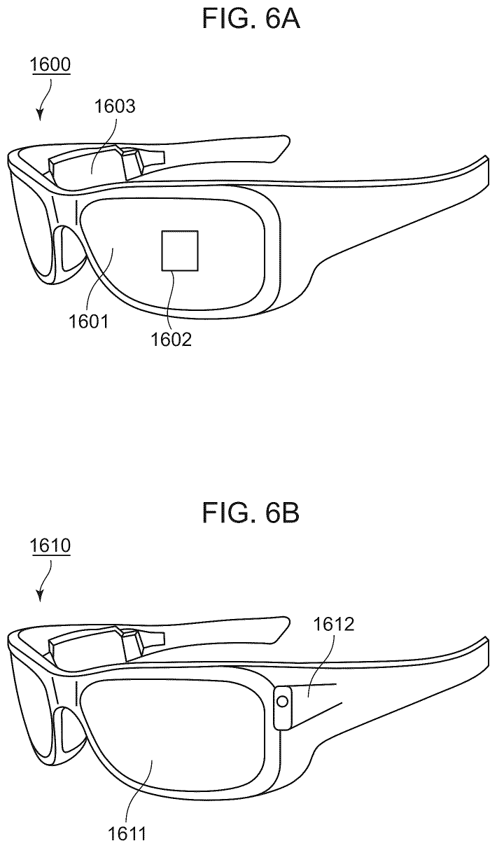

An application example of a display apparatus is described below with reference to FIGS. 6A and 6B. The display apparatus can be applied to a system that can be worn as a wearable device, such as smart glasses, a head-mounted display, or smart contact lenses. An imaging and displaying apparatus used in such an application example includes an imaging apparatus that can photoelectrically convert visible light and a display apparatus that can emit visible light.

Glasses 1600 (smart glasses) are described below with reference to FIG. 6A. An imaging apparatus 1602, such as a CMOS sensor or a SPAD sensor, is provided on the front side of a lens 1601 of the glasses 1600. The complementary metal-oxide-semiconductor (CMOS) sensor is a solid-state imaging element including a complementary metal-oxide semiconductor. The single photon avalanche diode (SPAD) sensor is a sensor with an electronic element that outputs one large electrical pulse signal by multiplication like an avalanche when one photon is incident on a pixel. A display apparatus is provided on the back side of the lens 1601. The glasses 1600 further include a controller 1603. The controller 1603 functions as a power supply for supplying power to the imaging apparatus 1602 and the display apparatus. The controller 1603 controls the operation of the imaging apparatus 1602 and the display apparatus. The lens 1601 has an optical system for focusing light on the imaging apparatus 1602.

Glasses 1610 (smart glasses) are described below with reference to FIG. 6B. The glasses 1610 have a controller 1612, which includes an imaging apparatus corresponding to the imaging apparatus 1602 and a display apparatus. A lens 1611 includes an optical system for projecting light from the imaging apparatus and the display apparatus of the controller 1612, and an image is projected on the lens 1611. The controller 1612 functions as a power supply for supplying power to the imaging apparatus and the display apparatus and controls the operation of the imaging apparatus and the display apparatus. The controller may include a line-of-sight detection unit for detecting the line of sight of the wearer. Infrared radiation may be used to detect the line of sight. An infrared radiation unit emits infrared light to an eyeball of a user who is gazing at a display image. Reflected infrared light from the eyeball is detected by an imaging unit including a light-receiving element to capture an image of the eyeball. A reduction unit for reducing light from the infrared radiation unit to a display unit in a plan view is provided to reduce degradation in image quality.

The glasses 1610 detect the line of sight of the user for the display image from the image of the eyeball captured by infrared imaging. Any known technique can be applied to line-of-sight detection using the captured image of the eyeball. For example, it is possible to use a line-of-sight detection method based on a Purkinje image obtained by the reflection of irradiation light by the cornea. More specifically, a line-of-sight detection process based on a pupil-corneal reflection method is performed. The line of sight of the user is detected by calculating a line-of-sight vector representing the direction (rotation angle) of an eyeball on the basis of an image of a pupil and a Purkinje image included in a captured image of the eyeball using the pupil-corneal reflection method.

The display apparatus may include an imaging apparatus including a light-receiving element and may control a display image on the basis of line-of-sight information of a user from the imaging apparatus. More specifically, the display apparatus determines, based on the line-of-sight information, a first visibility region at which the user gazes and a second visibility region other than the first visibility region. The first visibility region and the second visibility region may be determined by the controller of the display apparatus or may be received from an external controller. In the display region of the display apparatus, the display resolution of the first visibility region may be controlled to be higher than the display resolution of the second visibility region. In other words, the resolution of the second visibility region may be lower than the resolution of the first visibility region.

Furthermore, the display region includes a first display region and a second display region different from the first display region, and a region with a high priority is determined from the first display region and the second display region based on the line-of-sight information. The first display region and the second display region may be determined by the controller of the display apparatus or may be received from an external controller. A region with a higher priority may be controlled to have higher resolution than another region. In other words, a region with a lower priority may have lower resolution.

Artificial intelligence (AI) may be used to determine the first visibility region and the region with a high priority. The AI may be a model configured to estimate the angle of the line of sight and the distance to a target ahead of the line of sight from an image of an eyeball using the image of the eyeball and the direction in which the eyeball actually viewed in the image as teaching data. The AI program may be stored in the display apparatus, the imaging apparatus, or an external apparatus. The AI program stored in an external apparatus is transmitted to the display apparatus via communication. For display control based on visual recognition detection, the present invention can be applied to smart glasses further having an imaging apparatus for imaging the outside. Smart glasses can display captured external information in real time.

As described above, an apparatus including an organic light emitting device according to the present invention can be used to stably display a high-quality image for extended periods. It is also possible to achieve both good outdoor visibility and power-saving display by high-efficiency and high-luminance light output.

### EXEMPLARY EMBODIMENTS

Although the present invention is described below in more detail in the exemplary embodiments and comparative examples, the present invention is not limited to these exemplary embodiments within the gist of the present invention. Unless otherwise specified, “part(s)” and “%” with respect to the amount of component are based on mass. 1 ppm can be converted to 0.0001% by mass unless otherwise specified.

### <Preparation of Light Emitting Composition>

An organometallic complex, a fluorene oligomer, a polymer host material, an additive agent, and 9,900 parts of cyclopentanone as an organic solvent, which were of the types and amounts (parts) shown in Tables 1 to 4, were mixed and stirred at 25° C. for 24 hours. The mixture was then filtered through a filter with a pore size of 0.2 μm to prepare each light emitting composition (liquid light emitting composition). Table 5 shows the structure (the number of repetitions of the unit, the functional group) of each fluorene oligomer in Tables 1 to 4. In Table 5, when a fluorene oligomer is a compound including a plurality of types of units with different substituents, a functional group characterizing the compound is described.

The compounds in Tables 1 to 4 are as follows: Organometallic complexes 35, 41, and 48: compounds exemplified as organometallic complexes
Organometallic complex 100: a compound represented by the following structural formula:

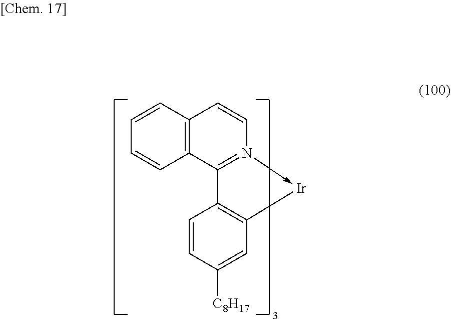

Fluorene Oligomers 101, 105, 108, 109, 115, and 116: compounds exemplified above as fluorene oligomers
Fluorene oligomers 119 to 125: compounds represented by the following structural formulae:

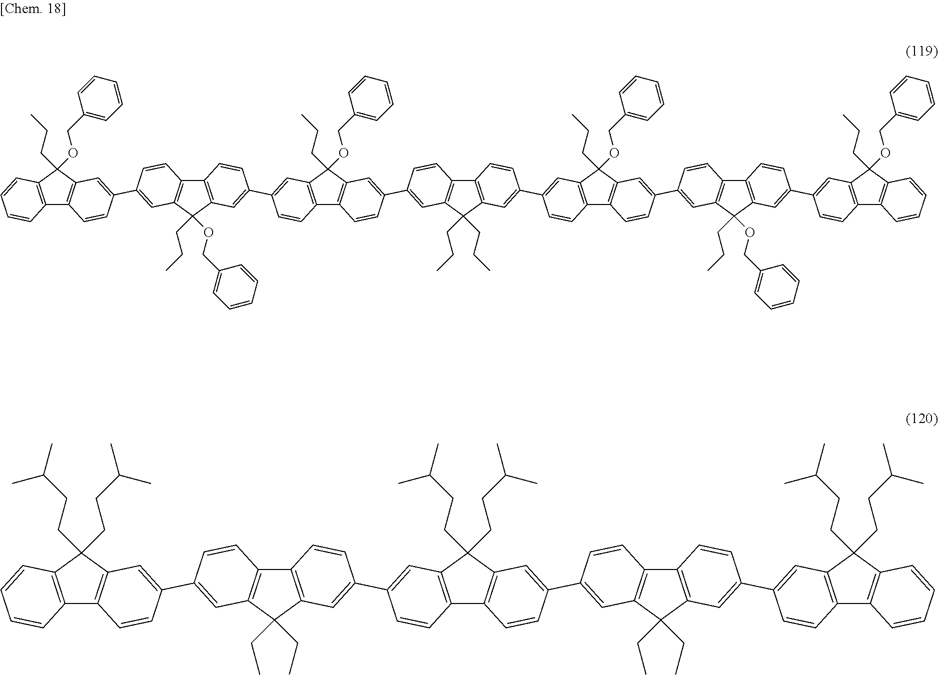

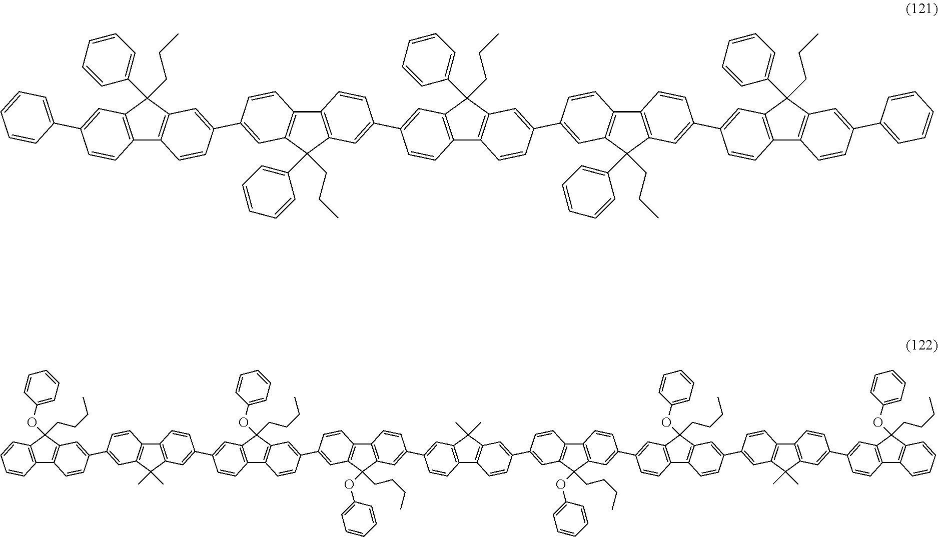

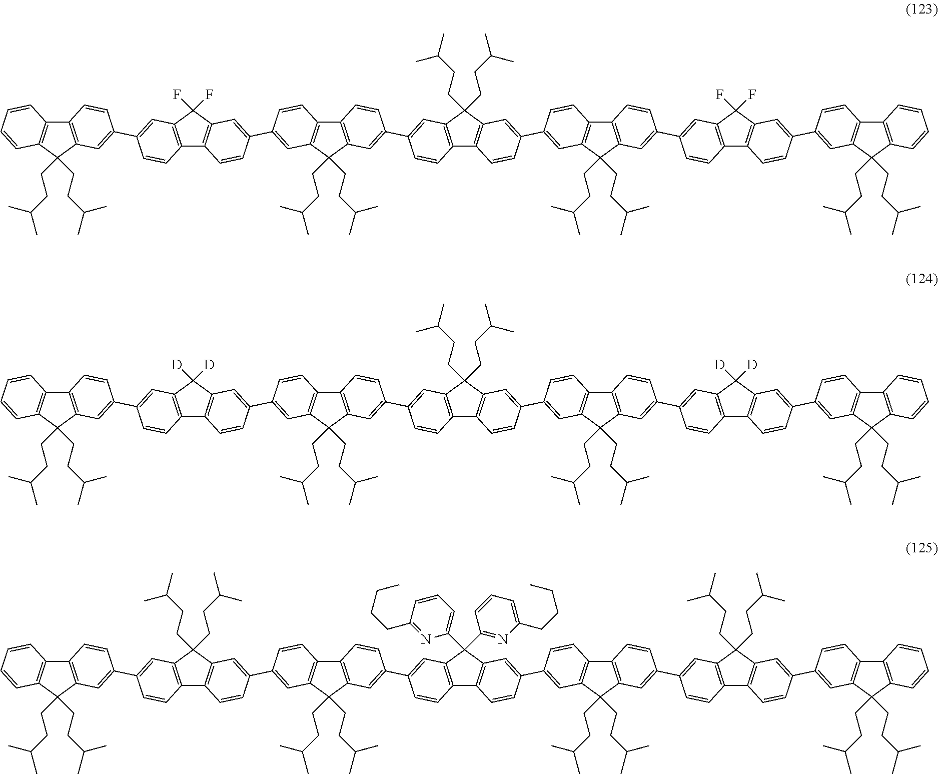

Polymer host materials 201, 202, and 203: compounds represented by the following structural formulae (the polymer host materials 201 and 203 are compounds with hole transport properties)
Weight-average molecular weight of the polymer host material 201: approximately 1,100,000
Weight-average molecular weight of the polymer host material 202: more than 20,000 and 2,000,000 or less
Weight-average molecular weight of the polymer host material 203: 20,000 to 200,000

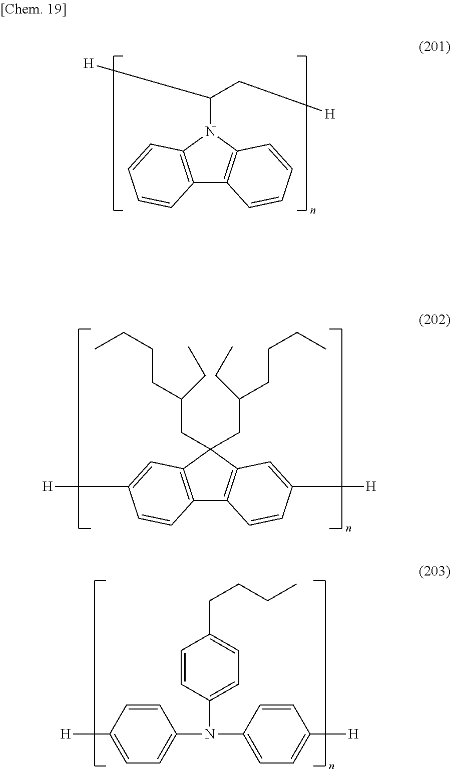

Additive agent 301: an electron transport material represented by the following structural formula (trade name “OXD-7”, manufactured by Luminescence Technology)

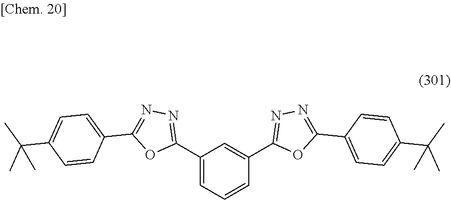 [SMILES: CC(C)(C)c1ccc(-c2nnc(-c3cccc(-c4nnc(-c5ccc(C(C)(C)C)cc5)o4)c3)o2)cc1]

TABLE 1
Compositions and properties of prepared light emitting liquid compositions

| | | Exemplary embodiment | | | | | | | | |
|---|---|---|---|---|---|---|---|---|---|---|
| | | 1 | 2 | 3 | 4 | 5 | 6 | 7 | 8 | 9 |
| Organometallic | 35 | 1.0 | 1.0 | 0.5 | 1.0 | 1.0 | 1.0 | 1.0 | 1.0 | 1.0 |
| complex M | 41 | | | 0.5 | | | | | | |
| | 48 | | | | | | | | | |
| | 100 | | | | | | | | | |
| Fluorene | 101 | 69.3 | | | | | | | | |
| oligomer O | 108 | | 69.3 | 69.3 | 49.5 | 29.7 | | | | |
| | 109 | | | | | | | | | |
| | 105 | | | | | | 29.7 | | | |
| | 115 | | | | | | | 69.3 | | |
| | 116 | | | | | | | | 69.3 | |
| | 119 | | | | | | | | | |
| | 120 | | | | | | | | | |
| | 121 | | | | | | | | | |
| | 122 | | | | | | | | | 69.3 |
| | 123 | | | | | | | | | |
| | 124 | | | | | | | | | |
| | 125 | | | | | | | | | |
| Polymer host | 201 | 29.7 | 29.7 | 29.7 | 29.7 | 69.3 | 69.3 | 29.7 | 29.7 | 29.7 |
| material H | 202 | | | | | | | | | |
| | 203 | | | | | | | | | |
| Additive agent | 301 | | | | 19.8 | | | | | |
| Organic solvent | Cyclopentanone | 9,900 | 9,900 | 9,900 | 9,900 | 9,900 | 9,900 | 9,900 | 9,900 | 9,900 |
| Properties | Organometallic | 100 | 100 | 100 | 100 | 100 | 100 | 100 | 100 | 100 |
| | complex M | | | | | | | | | |
| | content (ppm) | | | | | | | | | |
| | Fluorene | 6,930 | 6,930 | 6,930 | 4,950 | 2,970 | 2,970 | 6,930 | 6,930 | 6,930 |
| | oligomer O | | | | | | | | | |
| | content (ppm) | | | | | | | | | |
| | Polymer host | 2,970 | 2,970 | 2,970 | 2,970 | 6,930 | 6,930 | 2,970 | 2,970 | 2,970 |
| | material H | | | | | | | | | |
| | content (ppm) | | | | | | | | | |
| | M/(O + H) (times) | 0.01 | 0.01 | 0.01 | 0.01 | 0.01 | 0.01 | 0.01 | 0.01 | 0.01 |
| | O/(O + H) (times) | 0.70 | 0.70 | 0.70 | 0.63 | 0.30 | 0.30 | 0.70 | 0.70 | 0.70 |

TABLE 2
Compositions and properties of prepared light emitting liquid compositions

| | | Exemplary embodiment | | | | | | | | |
|---|---|---|---|---|---|---|---|---|---|---|
| | | 10 | 11 | 12 | 13 | 14 | 15 | 16 | 17 | 18 |
| Organometallic | 35 | 1.0 | | 1.0 | 1.0 | | | 1.0 | 1.0 | 0.04 |
| complex M | 41 | | 1.0 | | | | 1.0 | | | |
| | 48 | | | | | 1.0 | | | | |
| | 100 | | | | | | | | | |
| Fluorene | 101 | | | | | | | | | |
| oligomer O | 108 | | | 69.3 | 69.3 | | 9.9 | | 93.0 | 24.5 |
| | 109 | | | | | 5.0 | | 90.0 | | |
| | 105 | | | | | | | | | |
| | 115 | | | | | | | | | |
| | 116 | | | | | | | | | |
| | 119 | | 49.5 | | | | | | | |
| | 120 | | | | | | | | | |
| | 121 | | | | | | | | | |
| | 122 | | | | | | | | | |
| | 123 | 69.3 | | | | | | | | |
| | 124 | | | | | | | | | |
| | 125 | | | | | | | | | |
| Polymer host | 201 | 29.7 | 49.5 | | | 56.4 | 89.1 | 5.4 | 3.4 | 75.0 |
| material H | 202 | | | 17.8 | | | | | | |
| | 203 | | | | 29.7 | | | | | |
| Additive agent | 301 | | | 11.9 | | 37.6 | | 3.6 | 2.6 | 0.46 |
| Organic solvent | Cyclopentanone | 9,900 | 9,900 | 9,900 | 9,900 | 9,900 | 9,900 | 9,900 | 9,900 | 9,900 |
| Properties | Organometallic | 100 | 100 | 100 | 100 | 100 | 100 | 100 | 100 | 4 |
| | complex M | | | | | | | | | |
| | content (ppm) | | | | | | | | | |
| | Fluorene | 6,930 | 4,950 | 6,930 | 6,930 | 500 | 990 | 9,000 | 9,300 | 2,450 |
| | oligomer O | | | | | | | | | |
| | content (ppm) | | | | | | | | | |
| | Polymer host | 2,970 | 4,950 | 1,780 | 2,970 | 5,640 | 8,910 | 540 | 340 | 7,500 |
| | material H | | | | | | | | | |
| | content (ppm) | | | | | | | | | |
| | M/(O + H) (times) | 0.01 | 0.01 | 0.01 | 0.01 | 0.02 | 0.01 | 0.01 | 0.01 | 0.0004 |
| | O/(O + H) (times) | 0.70 | 0.50 | 0.80 | 0.70 | 0.08 | 0.10 | 0.94 | 0.96 | 0.25 |

TABLE 3
Compositions and properties of prepared light emitting liquid compositions

| | | Exemplary embodiment | | | | | | Comparative example | | |
|---|---|---|---|---|---|---|---|---|---|---|
| | | 19 | 20 | 21 | 22 | 23 | 24 | 1 | 2 | 3 |
| Organometallic | 35 | 0.5 | | | | 1.0 | 1.0 | 1.0 | | |
| complex M | 41 | | | | | | | | 15.0 | |
| | 48 | | 14.0 | 15.0 | 15.0 | | | | | 0.04 |
| | 100 | | | | | | | | | |
| Fluorene | 101 | | | | | | | | | |
| oligomer O | 108 | 24.5 | 46.0 | | | | | 99.0 | | |
| | 109 | | | | | | | | 70.0 | |
| | 105 | | | 50.0 | | | | | | |
| | 115 | | | | | | | | | |
| | 116 | | | | | | | | | |
| | 119 | | | | 67.2 | | | | | |
| | 120 | | | | | | | | | |
| | 121 | | | | | | | | | |
| | 122 | | | | | | | | | |
| | 123 | | | | | | | | | |
| | 124 | | | | | 69.3 | | | | |
| | 125 | | | | | | 69.3 | | | |
| Polymer host | 201 | 75.0 | 24.0 | 20.0 | | 29.7 | 29.7 | | | 99.96 |
| material H | 202 | | | | 2.8 | | | | | |
| | 203 | | | | | | | | | |
| Additive agent | 301 | | 16.0 | 15.0 | 15.0 | | | | 15.0 | |
| Organic solvent | Cyclopentanone | 9,900 | 9,900 | 9,900 | 9,900 | 9,900 | 9,900 | 9,900 | 9,900 | 9,900 |
| Properties | Organometallic | 50 | 1,400 | 1,500 | 1,500 | 100 | 100 | 100 | 1,500 | 4 |
| | complex M | | | | | | | | | |
| | content (ppm) | | | | | | | | | |
| | Fluorene | 2,450 | 4,600 | 5,000 | 6,720 | 6,930 | 6,930 | 9,900 | 7,000 | 0 |
| | oligomer O | | | | | | | | | |
| | content (ppm) | | | | | | | | | |
| | Polymer host | 7,500 | 2,400 | 2,000 | 280 | 2,970 | 2,970 | 0 | 0 | 9,996 |
| | material H | | | | | | | | | |
| | content (ppm) | | | | | | | | | |
| | M/(O + H) (times) | 0.005 | 0.20 | 0.21 | 0.21 | 0.01 | 0.01 | 0.01 | 0.21 | 0.0004 |
| | O/(O + H) (times) | 0.25 | 0.66 | 0.71 | 0.96 | 0.70 | 0.70 | 1.00 | 1.00 | 0.00 |

TABLE 4
Compositions and properties of prepared light emitting liquid compositions

| | | Comparative example | | | | | | | | |
|---|---|---|---|---|---|---|---|---|---|---|
| | | 4 | 5 | 6 | 7 | 8 | 9 | 10 | 11 | 12 |
| Organometallic | 35 | | 1.0 | 1.0 | | | | | 1.0 | |
| complex M | 41 | 1.0 | | | | | | 1.0 | | |
| | 48 | | | | | | | | | 1.0 |
| | 100 | | | | 1.0 | 1.0 | 1.0 | | | |
| Fluorene | 101 | | | | | | | | | |
| oligomer O | 108 | | | | | | | | | |
| | 109 | | | | | 99.0 | 79.2 | | | |
| | 105 | | | | 5.0 | | | | | |
| | 115 | | | | | | | | | |
| | 116 | | | | | | | | | |
| | 119 | | | | | | | | | |
| | 120 | 90.0 | | | | | | | | |
| | 121 | | | | | | | 49.5 | | |
| | 122 | | | | | | | | | |
| | 123 | | | | | | | | | |
| | 124 | | | | | | | | | |
| | 125 | | | | | | | | | |
| Polymer host | 201 | 5.4 | 41.6 | 59.4 | | | | 49.5 | | |
| material H | 202 | | 29.7 | | 94.0 | | 19.8 | | 99.0 | 99.0 |
| | 203 | | | | | | | | | |
| Additive agent | 301 | 3.6 | 27.7 | 39.6 | | | | | | |
| Organic solvent | Cyclopentanone | 9,900 | 9,900 | 9,900 | 9,900 | 9,900 | 9,900 | 9,900 | 9,900 | 9,900 |
| Properties | Organometallic | 100 | 100 | 100 | 100 | 100 | 100 | 100 | 100 | 100 |
| | complex M | | | | | | | | | |
| | content (ppm) | | | | | | | | | |
| | Fluorene | 9,000 | 0 | 0 | 500 | 9,900 | 7,920 | 4,950 | 0 | 0 |
| | oligomer O | | | | | | | | | |
| | content (ppm) | | | | | | | | | |
| | Polymer host | 540 | 7,130 | 5,940 | 9,400 | 0 | 1,980 | 4,950 | 9,900 | 9,900 |
| | material H | | | | | | | | | |
| | content (ppm) | | | | | | | | | |
| | M/(O + H) (times) | 0.01 | 0.01 | 0.02 | 0.01 | 0.01 | 0.01 | 0.01 | 0.01 | 0.01 |
| | O/(O + H) (times) | 0.94 | 0.00 | 0.00 | 0.05 | 1.00 | 0.80 | 0.50 | 0.00 | 0.00 |

TABLE 5
Structure of fluorene oligomer

| | Number of | |
|---|---|---|
| Fluorene | repetitions of | Functional group at 9-position/ |
| oligomer | unit | 9-position of unit |
| 101 | 6 | 3-methylbutyl group/3-methylbutyl group |
| 108 | 9 | 3-methylbutyl group/3-methylbutyl group |
| 109 | 9 | 3-methylbutyl group/3-methylbutyl group |
| 105 | 7 | 2-methylbutyl group/2-methylbutyl group |
| 115 | 12 | 3-methylbutyl group/3-methylbutyl group |
| 116 | 7 | Hexyl group/hexyl group |
| 119 | 7 | Propyl group/benzyloxy group |
| 120 | 5 | 3-methylbutyl group/3-methylbutyl group |
| 121 | 5 | Phenyl group/propyl group |
| 122 | 9 | Butyl group/phenoxy group |
| 123 | 7 | Fluorine atom/fluorine atom |
| 124 | 7 | Deuterium atom/deuterium atom |
| 125 | 7 | 3-butyl-2-pyridyl group/3-butyl-2-pyridyl group |

### <Manufacturing of Organic Light Emitting Device>

According to the following procedure, a positive electrode, a hole injection layer, a light emitting layer, an electron transport layer, and a negative electrode were sequentially formed on a substrate to manufacture an organic light emitting device. A glass substrate on which an ITO film with a thickness of 100 nm was formed as a positive electrode by a sputtering method was used as a transparent electrically conductive supporting substrate (ITO substrate). The ITO substrate was washed with pure water and then with isopropanol and was subjected to UV-ozone treatment, and a hole injection layer was then formed by a spin coating method. The film formation conditions are as follows:
Coating liquid: aqueous poly(3,4-ethylenedioxythiophene) poly(styrene sulfonate) (aqueous PEDOT; PSS, manufactured by Aldrich, electrical conductivity: 1×10⁻⁵ S/cm, compound content: 2.8%)
Spin coating conditions: 3,000 rpm, 60 seconds
Anneal conditions: 200° C., 1 hour
Film thickness: 40 nm.

Next, a light emitting layer was formed by the spin coating method. The film formation conditions are as follows:
Coating liquid: light emitting composition described in Tables 1 to 4
Spin coating conditions: 3,000 rpm, 60 seconds
Anneal conditions: 110° C., 10 minutes
Film thickness: 30 nm.

Finally, an electron transport layer and an electrode layer were formed by a vacuum deposition method using resistance heating. Facing electrodes had an area of 3 mm². The film formation conditions are as follows:
Degree of vacuum: 1×10⁻⁵ Pa
Electron transport layer: TPBi (50 nm)
Metal electrode layer: LiF (0.5 nm), Al (90 nm).

Subsequently, the organic light emitting device was covered with a protective glass plate in a dry air atmosphere so as not to be degraded by adsorption of water, and the glass plate was sealed with an acrylic resin adhesive.

### <Evaluation>

The organic light emitting devices manufactured above were evaluated for the following items. In the present invention, in the evaluation criteria of the following items, “A” and “B” were acceptable, and “C” was unacceptable. Table 6 shows the evaluation results.

### (Measurement of Emission Quantum Yield)

The emission quantum yield of the host (hereinafter also referred to as PLQY (H)) and the emission quantum yield of the dopant (hereinafter also referred to as PLQY (D)) were measured in the organic light emitting devices. The measurement conditions include excitation light: 346 nm, host light emitting region: 400 to 550 nm, and dopant light emitting region: 550 to 800 nm, and an absolute emission quantum yield measuring apparatus (trade name “C11347-01”, manufactured by Hamamatsu Photonics K. K.) was used.

### (Emission Quantum Yield of Dopant Emission)

From PLQY (D) determined by the above measurement, the emission quantum yield of the dopant was rated according to the following evaluation criteria:
A: PLQY (D) was 72% or more.
B: PLOY (D) was 70% or more and less than 72%.
C: PLQY (D) was less than 70%.
   (Emission Quantum Yield of Host with Respect to Dopant)

PLQY (H)/PLQY (D) was calculated from PLQY (H) and PLQY (D) determined by the above measurement, and the ratio of the emission quantum yield of the host with respect to the dopant was rated according to the following evaluation criteria. A higher PLQY (H)/PLQY (D) means that the light emission of the host more affects the tint of the light emission of the dopant.
A: PLQY (H)/PLQY (D) was 6.5% or less.
B: PLQY (H)/PLQY (D) was more than 6.5% and 11.0% or less.
C: PLQY (H)/PLQY (D) was more than 11.0%.

TABLE 6
Evaluation results

| | | PLQY(D) | PLQY(H)/PLQY(D) |
|---|---|---|---|
| Exemplary | 1 | A | A |
| embodiment | 2 | A | A |
| | 3 | A | A |
| | 4 | A | A |
| | 5 | A | A |
| | 6 | A | A |
| | 7 | A | A |
| | 8 | A | A |
| | 9 | B | B |
| | 10 | B | B |
| | 11 | B | B |
| | 12 | B | B |
| | 13 | B | B |
| | 14 | A | B |
| | 15 | A | A |
| | 16 | A | A |
| | 17 | A | B |
| | 18 | B | B |
| | 19 | A | A |
| | 20 | A | A |
| | 21 | A | B |
| | 22 | B | B |
| | 23 | B | B |
| | 24 | B | B |
| Comparative | 1 | C | B |
| example | 2 | C | C |
| | 3 | C | B |
| | 4 | C | A |
| | 5 | C | C |
| | 6 | C | A |
| | 7 | C | C |
| | 8 | C | B |
| | 9 | C | C |
| | 10 | C | C |
| | 11 | A | C |
| | 12 | C | C |

Although the rating of the light emitting composition of Exemplary Embodiment 12 was the same rank B as the light emitting composition of Exemplary Embodiment 13, the light emitting composition of Exemplary Embodiment 13 was superior in terms of the emission quantum yield of dopant emission and the emission quantum yield of a host with respect to a dopant. Furthermore, although the rating of the light emitting composition of Exemplary Embodiment 22 was the same rank B as the light emitting compositions of Exemplary Embodiments 9 to 13, 18, 23, and 24, among these, the light emitting composition of Exemplary Embodiment 22 was inferior in terms of the emission quantum yield of dopant emission and the emission quantum yield of a host with respect to a dopant.

As Reference Example 1, an organic light emitting device was manufactured by sequentially forming a positive electrode, a hole injection layer, a light emitting layer, an electron transport layer, and a negative electrode on a substrate in the same manner as in Exemplary Embodiment 1 except that an ink jet method was used instead of the sputtering method. The rating of the organic light emitting device was “A” in both items.

The present invention is not limited to these embodiments, and various changes and modifications may be made therein without departing from the spirit and scope of the present invention. Accordingly, the following claims are attached to make the scope of the present invention public.

The present invention can provide a light emitting composition or the like that can improve the emission quantum yield of dopant emission and reduce the light emission of a host. Another aspect of the present invention can provide an organic light emitting device, a display apparatus, an imaging apparatus, electronic equipment, a lighting apparatus, and a moving body, each of which has a light emitting layer formed of the light emitting composition. Still another aspect of the present invention can provide a method for manufacturing an organic light emitting device using the light emitting composition.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting composition comprising:
an organometallic complex;
a fluorene oligomer; and
a polymer host material,
wherein the organometallic complex is at least one compound selected from the group consisting of a compound represented by the following general formula (1) and a compound represented by the following general formula (2), and
the fluorene oligomer is a compound containing a unit represented by the following general formula (6) and having a number of repetitions of the unit of 6 or more and 14 or less 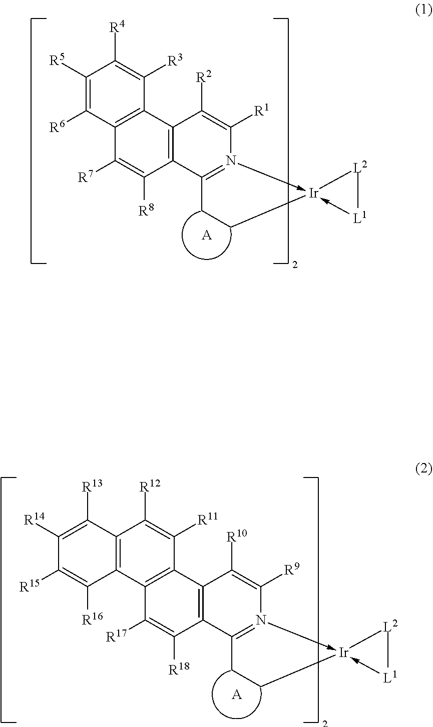
in the general formulae (1) and (2), R¹ to R¹⁸ each independently denote a hydrogen atom, a deuterium atom, a halogen atom, an alkyl group, a cycloalkyl group, an alkoxy group, an aryl group, a heteroaryl group, an aryloxy group, a heteroaryloxy group, a silyl group, an alkoxycarbonyl group, an acyl group, or a cyano group, a ring A represents an aryl ring or a heteroaryl ring, and L¹-L² represents a bidentate ligand represented by any one of the following general formulae (3) to (5) 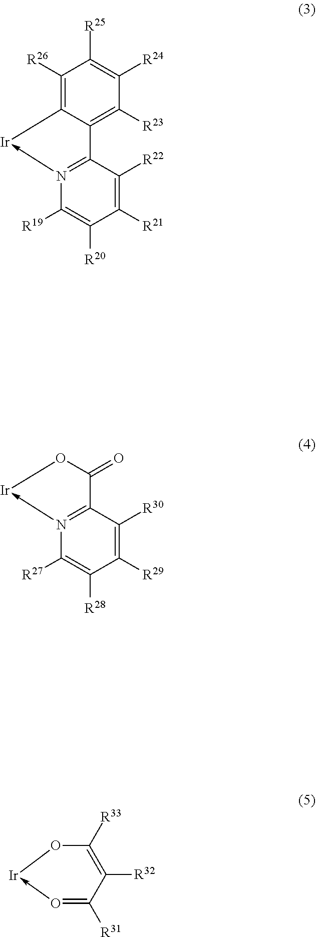
in the general formulae (3) to (5), R¹⁹ to R³³ each independently denote a hydrogen atom, a deuterium atom, a halogen atom, an alkyl group, a cycloalkyl group, an alkoxy group, an aryl group, or a heteroaryl group 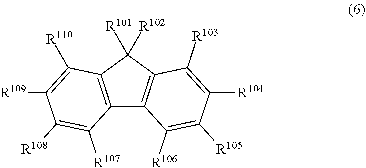
in the general formula (6), R¹⁰¹ and R¹⁰² each independently denote a hydrogen atom, a deuterium atom, a halogen atom, an alkyl group, a cycloalkyl group, an alkoxy group, an aryloxy group, or a heteroaryloxy group, and a plurality of units represented by the general formula (6) are bonded together at any one of R¹⁰³ to R¹⁰⁶ and any one of R¹⁰⁷ to R¹¹⁰, and R¹⁰³ to R¹¹⁰ that are not bonded to an adjacent molecular unit of the general formula (6) each independently denote a hydrogen atom, a deuterium atom, a halogen atom, an alkyl group, a cycloalkyl group, an alkoxy group, an aryl group, a heteroaryl group, an aryloxy group, a heteroaryloxy group, or an amino group.

2. The light emitting composition according to claim 1, wherein the aryl ring of the ring A is a benzene ring, a naphthalene ring, a fluorene ring, a phenanthrene ring, a 9,9-spirobifluorene ring, or a chrysene ring.

3. The light emitting composition according to claim 1, wherein the fluorene oligomer is at least one of the following compounds (101) to (118)

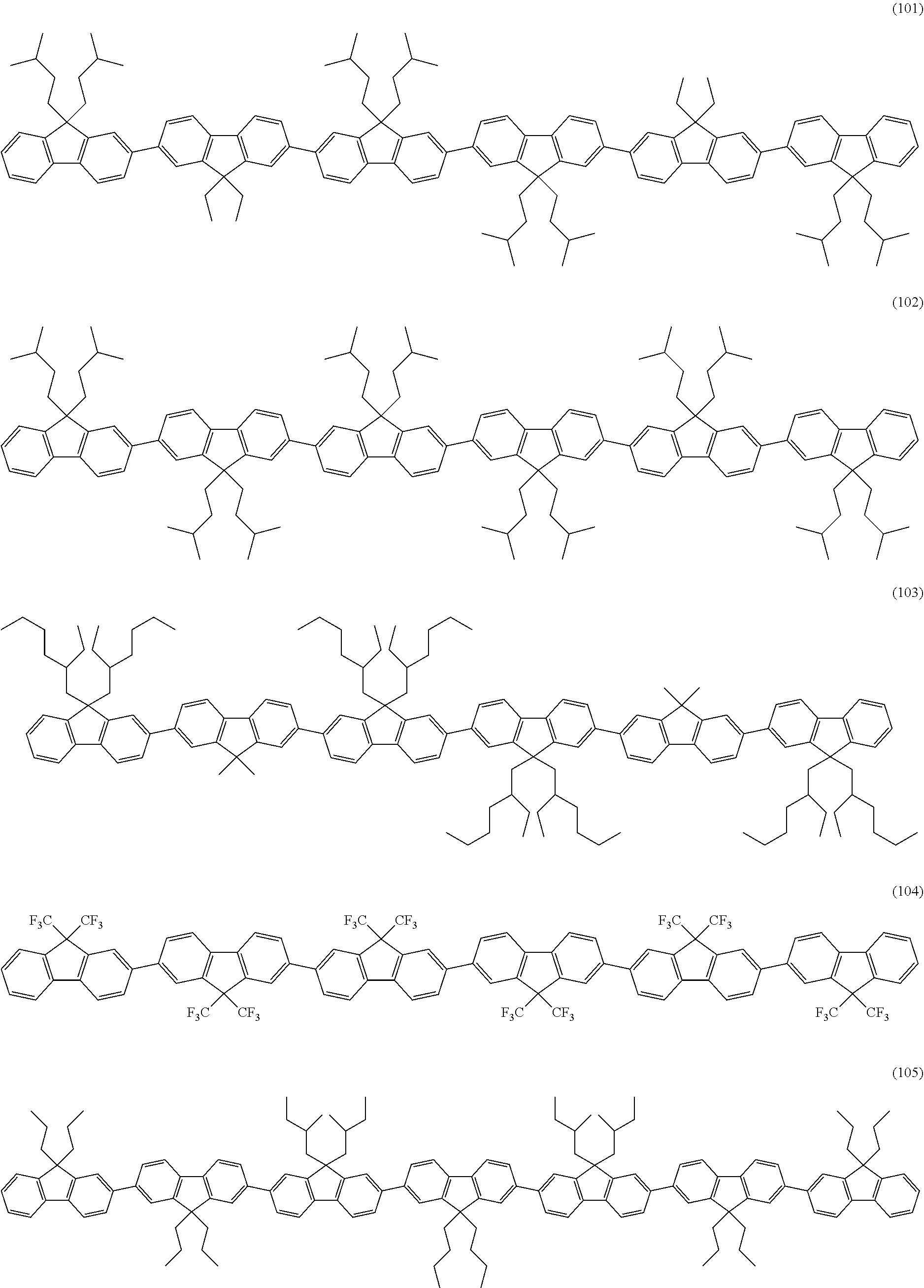

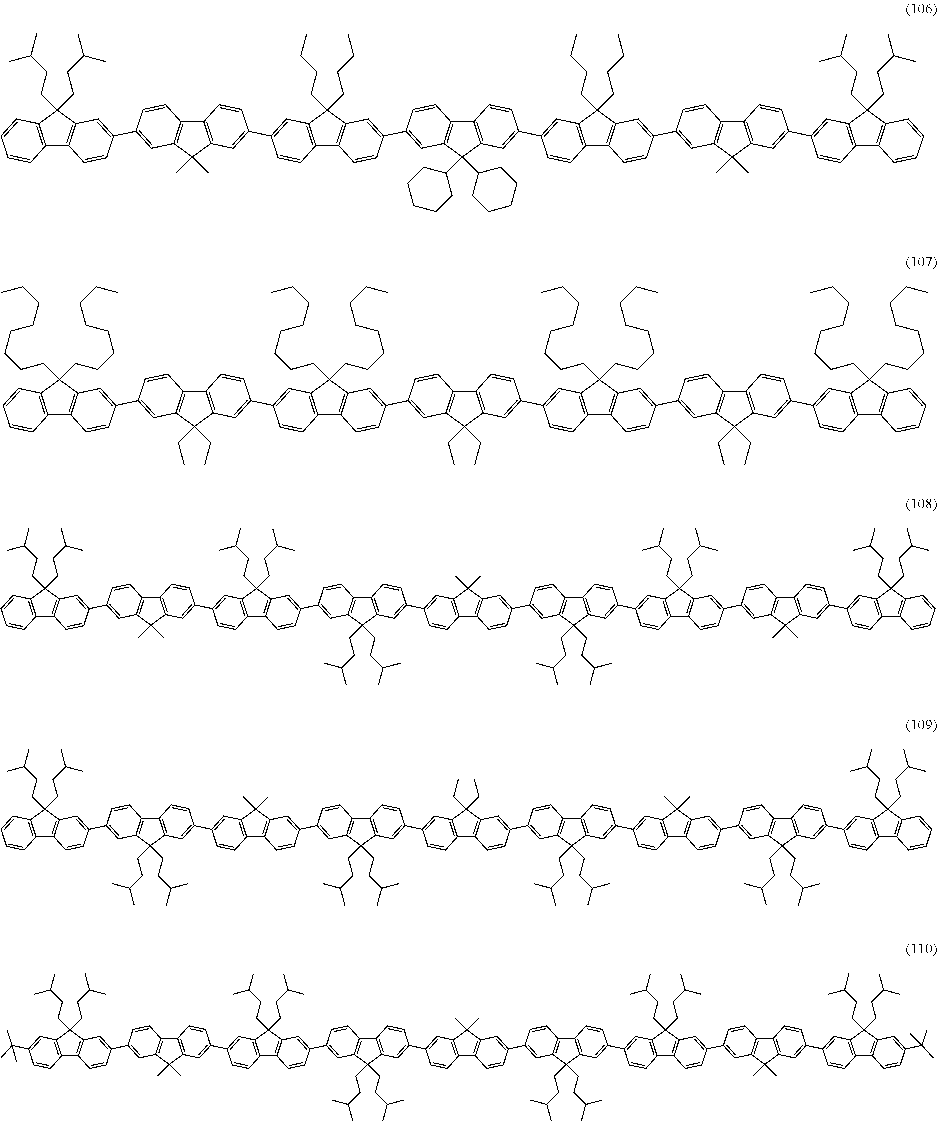

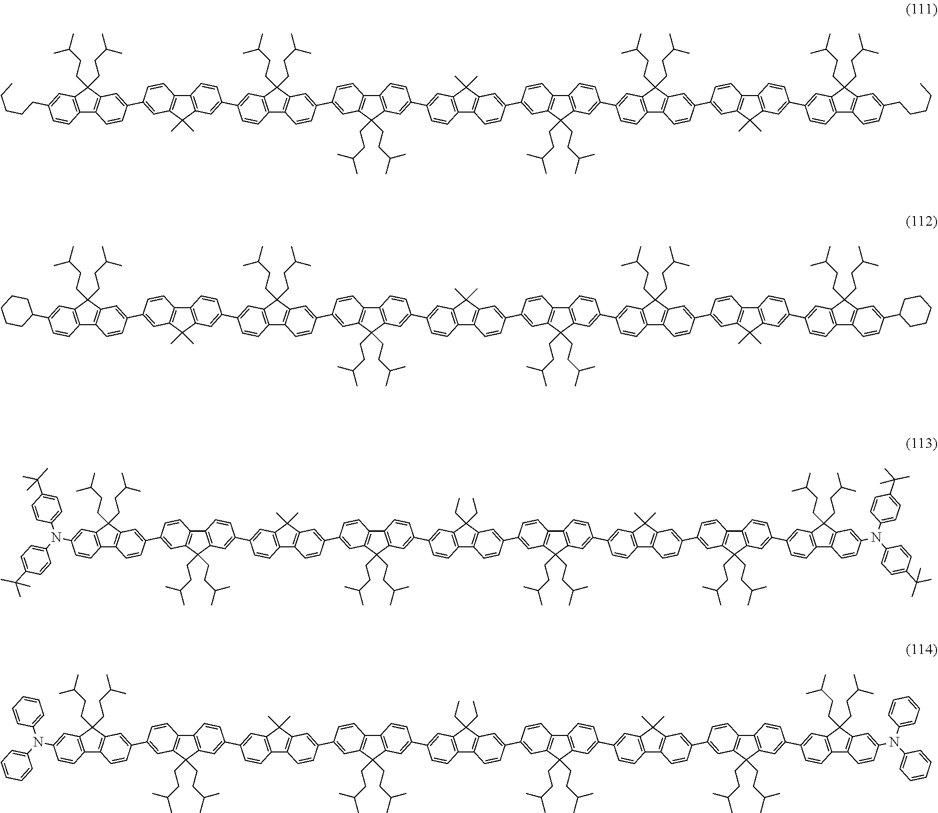

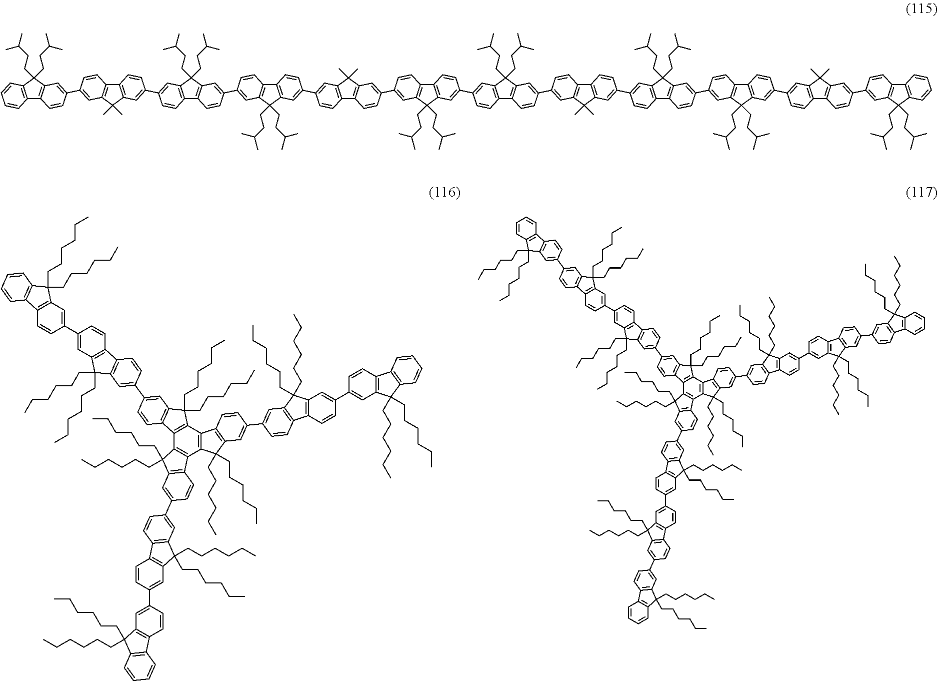

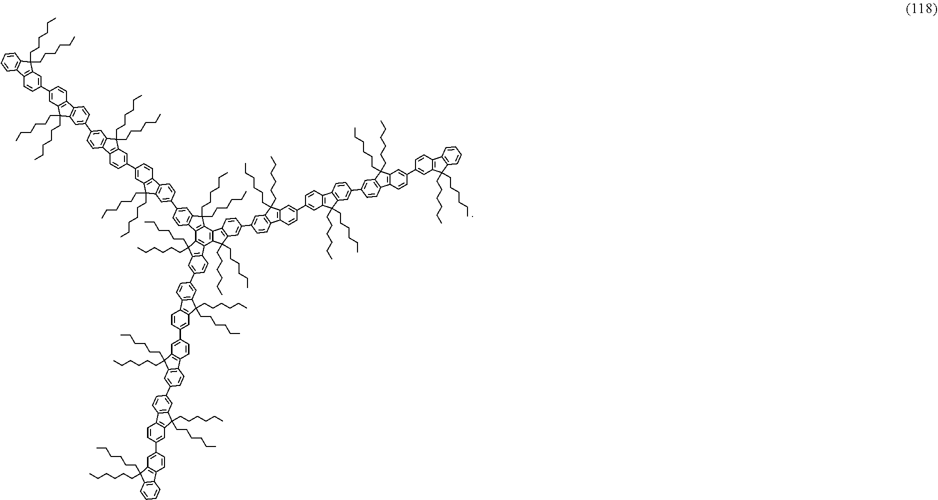

4. The light emitting composition according to claim 1, wherein the polymer host material has hole transport properties.

5. The light emitting composition according to claim 1, wherein the polymer host material is a compound represented by the following general formula (7) 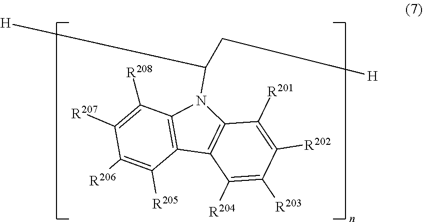
in the general formula (7), R²⁰¹ to R²⁰⁸ each independently denote a hydrogen atom, a deuterium atom, a halogen atom, an alkyl group, a cycloalkyl group, an alkoxy group, an aryl group, a heteroaryl group, an aryloxy group, or a heteroaryloxy group, and n is 50 or more and 10,000 or less.

6. The light emitting composition according to claim 1, wherein a fluorene oligomer content (ppm) of the light emitting composition is 0.10 times or more and 0.95 times or less by mass ratio based on a total of the fluorene oligomer content (ppm) and a polymer host material content (ppm).

7. The light emitting composition according to claim 1, wherein an organometallic complex content (ppm) of the light emitting composition is 0.001 times or more and 0.20 times or less by mass ratio based on a total of a fluorene oligomer content (ppm) and a polymer host material content (ppm).

8. The light emitting composition according to claim 1, wherein the light emitting composition is a liquid.

9. An organic light emitting device comprising:
a first electrode;
a second electrode; and
an organic compound layer that is a light emitting layer disposed between the first electrode and the second electrode,
wherein the organic compound layer is formed of the light emitting composition according to claim 1.

10. The organic light emitting device according to claim 9, wherein the light emitting layer further contains a first organic compound, and
the first organic compound has a lowest excited triplet energy equal to or higher than the lowest excited triplet energy of the organometallic complex and equal to or lower than the lowest excited triplet energy of the fluorene oligomer.

11. The organic light emitting device according to claim 10, wherein the organic compound layer further includes a first charge transport layer in contact with the first electrode between the first electrode and the light emitting layer and a second charge transport layer in contact with the second electrode between the second electrode and the light emitting layer.

12. The organic light emitting device according to claim 11, wherein the first charge transport layer has a lowest excited triplet energy higher than the lowest excited triplet energy of each of the polymer host material and the fluorene oligomer, and the second charge transport layer has a lowest excited triplet energy higher than the lowest excited triplet energy of each of the polymer host material and the fluorene oligomer.

13. A display apparatus comprising:
a plurality of pixels; and
a transistor coupled to the plurality of pixels,
wherein at least one of the plurality of pixels is the organic light emitting device according to claim 9.

14. An imaging apparatus comprising:
an optical unit including a plurality of lenses;
an imaging device configured to receive light passing through the optical unit; and
a display unit configured to display an image taken by the imaging device,
wherein the display unit includes the organic light emitting device according to claim 9.

15. Electronic equipment comprising:
a display unit;
a housing configured to be provided with the display unit; and
a communication unit provided in the housing and configured to communicate with an outside,
wherein the display unit includes the organic light emitting device according to claim 9.

16. A lighting apparatus comprising:
a light source; and
a member configured to transmit light emitted from the light source,
wherein the light source includes the organic light emitting device according to claim 9.

17. A moving body comprising:
a lamp; and
a body configured to be provided with the lamp,
wherein the lamp includes the organic light emitting device according to claim 9.

18. A method for manufacturing an organic light emitting device, comprising applying the light emitting composition according to claim 1 to a base material.

19. A method for manufacturing an organic light emitting device, comprising applying the light emitting composition according to claim 8 to a base material by a coating method or a printing method.

20. The method for manufacturing an organic light emitting device according to claim 19, wherein the coating method is a spin coating method, a casting method, a gravure coating method, a bar coating method, a roll coating method, a wire bar coating method, a dip coating method, a spray coating method, a capillary coating method, or a spray coating method.

21. The method for manufacturing an organic light emitting device according to claim 19, wherein the printing method is a screen method, a flexographic method, an offset method, or an ink jet method.
